(19) United States
(12) Patent Application Publication
(10) Pub. No.: US 2024/0047300 A1
(43) Pub. Date: Feb. 8, 2024

(54) SEMICONDUCTOR DEVICE

(71) Applicant: ROHM CO., LTD., Kyoto-shi (JP)

(72) Inventors: Xiaopeng WU, Kyoto-shi (JP); Oji SATO, Kyoto-shi (JP)

(21) Appl. No.: 18/489,512

(22) Filed: Oct. 18, 2023

Related U.S. Application Data
(63) Continuation of application No. PCT/JP2022/020468, filed on May 17, 2022.

(30) Foreign Application Priority Data
Jun. 9, 2021 (JP) 2021-096764

(51) Int. Cl. H01L 23/373; H01L 23/00; H01L 25/07

(52) U.S. Cl. CPC H01L 23/3735; H01L 24/48; H01L 24/32; H01L 25/072; H01L 23/3736; H01L 2224/48247; H01L 2224/48472; H01L 2224/32257; H01L 2924/13091; H01L 2924/01029; H01L 2924/01013

(57) ABSTRACT

A semiconductor device includes a support layer, a semiconductor element including an element metal layer facing the support layer, and a joining layer interposed between the support layer and the element metal layer. The element metal layer includes a first edge extending in a first direction orthogonal to a thickness direction of the semiconductor element. The joining layer includes a second edge located closest to the first edge and extending in the first direction. When the second edge is spaced apart from the element metal layer as viewed in the thickness direction, the distance from the first edge to the second edge in a second direction orthogonal to the thickness direction and the first direction is equal to or less than twice the thickness of the joining layer.

### TECHNICAL FIELD

The present disclosure relates to a semiconductor device.

### BACKGROUND ART

An example of a semiconductor device (power module) with a plurality of semiconductor elements bonded to a conductor layer is disclosed in JP-A-2016-162773. The semiconductor elements are bonded to the conductor layer via a solder layer. With such a configuration, the heat generated from the semiconductor elements during the use of the semiconductor device is conducted to the conductor layer via the solder layer.

For such a semiconductor device as disclosed in JP-A-2016-162773, however, it has been confirmed that the heat dissipation capability degrades in the long term at the bonding interfaces between the conductor layer and the semiconductor elements (the interface between the conductor layer and the solder layer and the interface between the solder layer and the semiconductor elements). Therefore, to improve the reliability of the semiconductor device, measures are needed to stabilize the heat dissipation capability at such bonding interfaces in the long term.

### BRIEF DESCRIPTION OF THE DRAWINGS

FIG. 1 is a perspective view of a semiconductor device according to a first embodiment of the present disclosure.

FIG. 2 is a perspective view corresponding to FIG. 1, from which illustration of a sealing resin is omitted.

FIG. 3 is a perspective view corresponding to FIG. 1, from which illustration of the sealing resin and a second conductive member is omitted.

FIG. 4 is a plan view of the semiconductor device shown in FIG. 1.

FIG. 5 is a plan view corresponding to FIG. 4, as seen through the sealing resin.

FIG. 6 is a partially enlarged view of FIG. 5.

FIG. 7 is a plan view corresponding to FIG. 4, from which illustration of the sealing resin and the second conductive member is omitted.

FIG. 8 is a right side view of the semiconductor device shown in FIG. 1.

FIG. 9 is a bottom view of the semiconductor device shown in FIG. 1.

FIG. 10 is a rear view of the semiconductor device shown in FIG. 1.

FIG. 11 is a front view of the semiconductor device shown in FIG. 1.

FIG. 12 is a sectional view taken along line XII-XII in FIG. 5.

FIG. 13 is a sectional view taken along line XIII-XIII in FIG. 5.

FIG. 14 is a partially enlarged view of FIG. 13.

FIG. 15 is a sectional view taken along line XV-XV in FIG. 5.

FIG. 16 is a sectional view taken along line XVI-XVI in FIG. 5.

FIG. 17 is a sectional view taken along line XVII-XVII in FIG. 5.

FIG. 18 is a partially enlarged view of FIG. 7.

FIG. 19 is a sectional view taken along line XIX-XIX in FIG. 18.

FIG. 20 is a partially enlarged view of FIG. 19.

FIG. 21 is a partially enlarged view of FIG. 19.

FIG. 22 is a sectional view taken along line XXII-XXII in FIG. 18.

FIG. 23 is a partially enlarged view of FIG. 22.

FIG. 24 is a circuit diagram of the semiconductor device shown in FIG. 1.

FIG. 25 is a partially enlarged plan view of a first variation of the semiconductor device shown in FIG. 1, as seen through the sealing resin.

FIG. 26 is a sectional view taken along line XXVI-XXVI in FIG. 25.

FIG. 27 is a partially enlarged plan view of a second variation of the semiconductor device shown in FIG. 1, as seen through the sealing resin.

FIG. 28 is a sectional view taken along line XXVIII-XXVIII in FIG. 27.

FIG. 29 is a partially enlarged sectional view of a semiconductor device according to a second embodiment of the present disclosure.

FIG. 30 is a partially enlarged sectional view of the semiconductor device shown in FIG. 29.

FIG. 31 is a partially enlarged view of FIG. 29.

FIG. 32 is a partially enlarged sectional view of a variation of the semiconductor device shown in FIG. 29.

FIG. 33 is a partially enlarged sectional view of a semiconductor device according to a third embodiment of the present disclosure.

FIG. 34 is a partially enlarged sectional view of the semiconductor device shown in FIG. 33.

### DETAILED DESCRIPTION OF EMBODIMENTS

The following describes modes for carrying out the present disclosure with reference to the drawings.

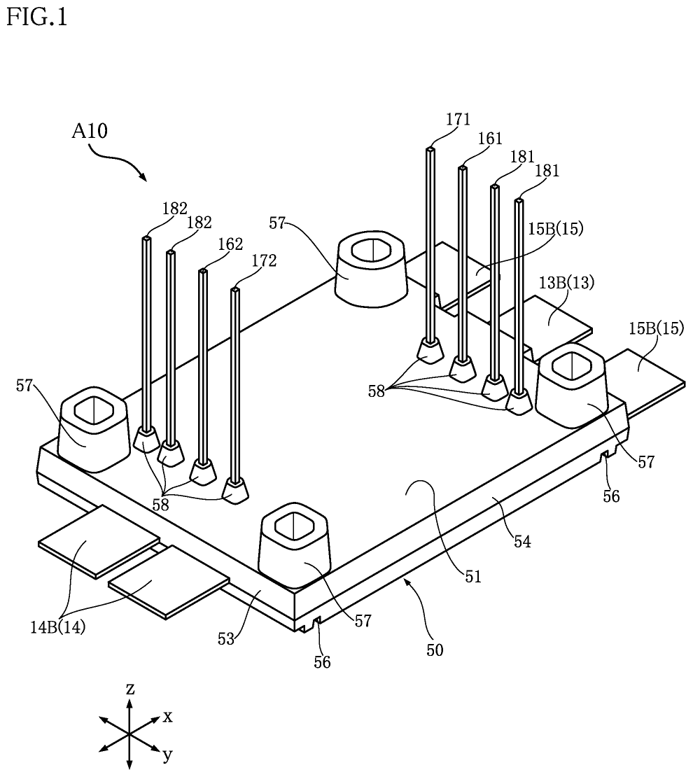

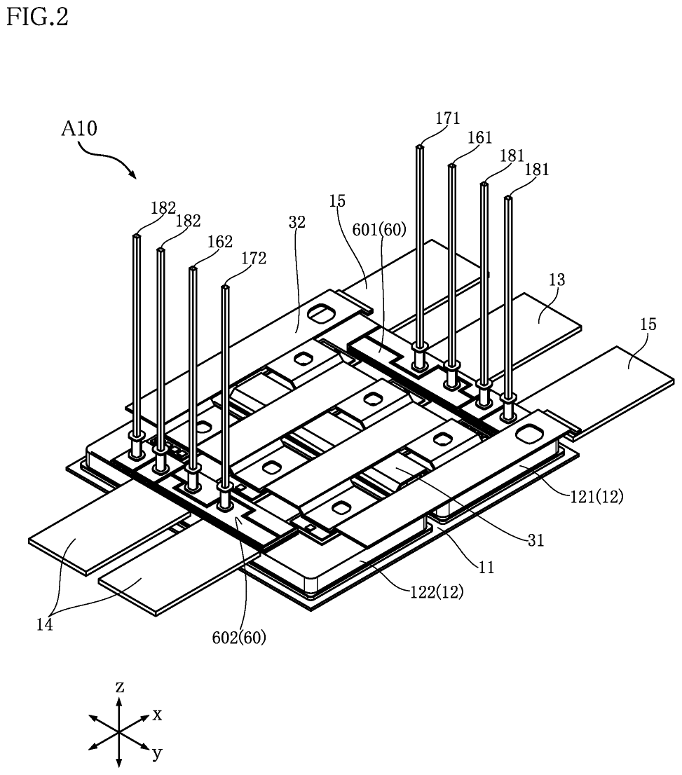

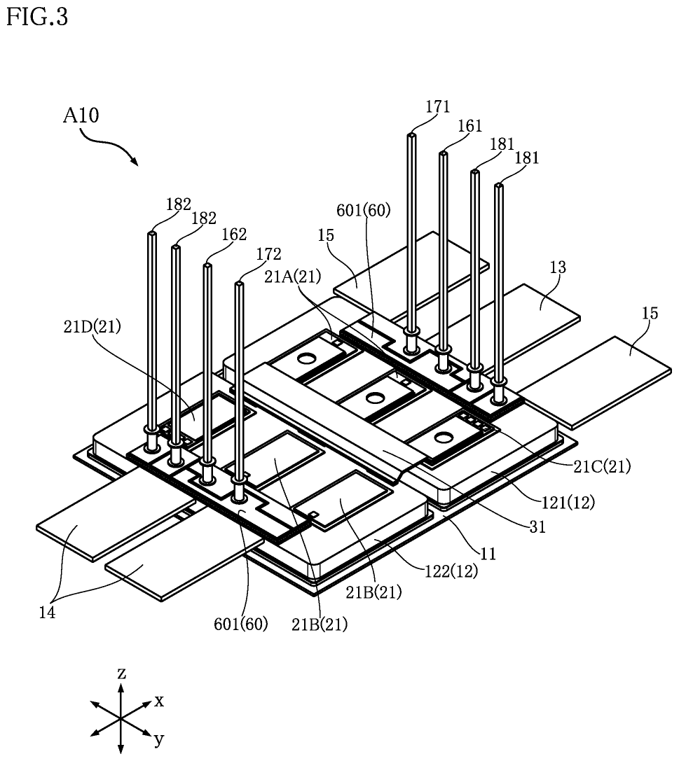

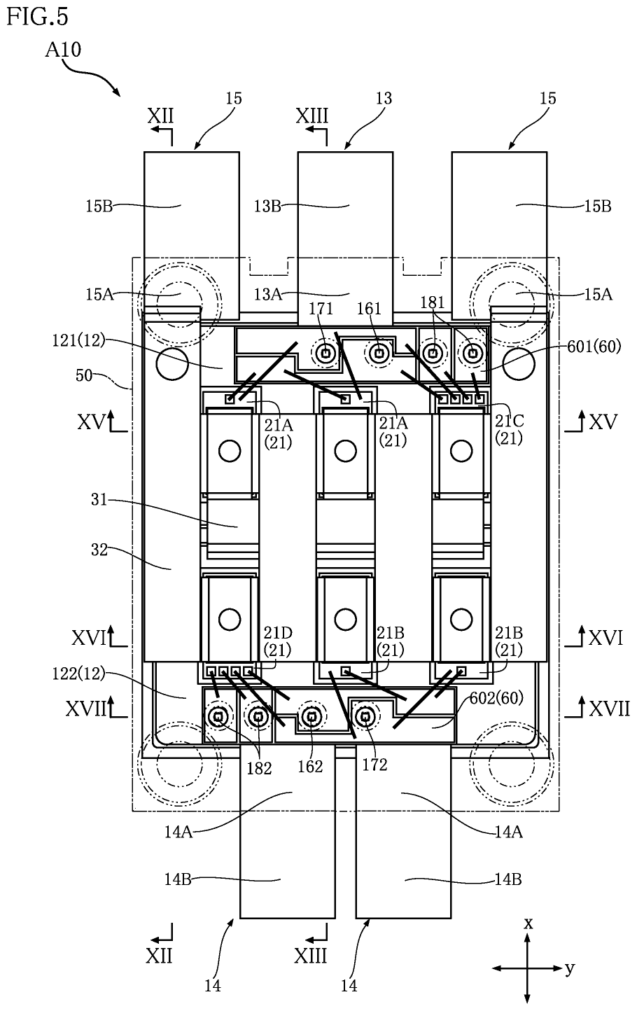

A semiconductor device A10 according to a first embodiment of the present disclosure is described below with reference to FIGS. 1 to 24. The semiconductor device A10 includes a support member 11, a support layer 12, a first input terminal 13, an output terminal 14, a second input terminal 15, a pair of first gate terminals 161, a pair of second gate terminals 162, a plurality of semiconductor elements 21, joining layers 23, a first conductive member 31, a second conductive member 32, a plurality of gate wires 41, and a sealing resin 50. The semiconductor device A10 further includes a pair of first detection terminals 171, a pair of second detection terminals 172, a pair of first diode terminals 181, a pair of second diode terminals 182, a plurality of detection wires 42, a plurality of diode wires 43, and a pair of control wirings 60. In FIGS. 2, 3, 5 to 7 and 18, the sealing resin 50 is shown transparent for convenience of understanding. In FIG. 5, the sealing resin 50 is indicated by imaginary lines (two-dot chain lines). In FIGS. 3, 7 and 18, the second conductive member 32 is also shown transparent for convenience of understanding.

In the description of the semiconductor device A10, the thickness direction of the semiconductor element 21 is referred to as a “thickness direction z” for convenience. A direction orthogonal to the thickness direction z is referred to as a “first direction x”. The direction orthogonal to the thickness direction z and the first direction x is referred to as a “second direction y”.

The semiconductor device A10 converts the DC power supply voltage applied to the first input terminal 13 and the second input terminal 15 into AC power by the semiconductor element 21. The converted AC power is inputted through the output terminal 14 to a power supply target such as a motor. The semiconductor device A10 is used in a power conversion circuit, such as an inverter.

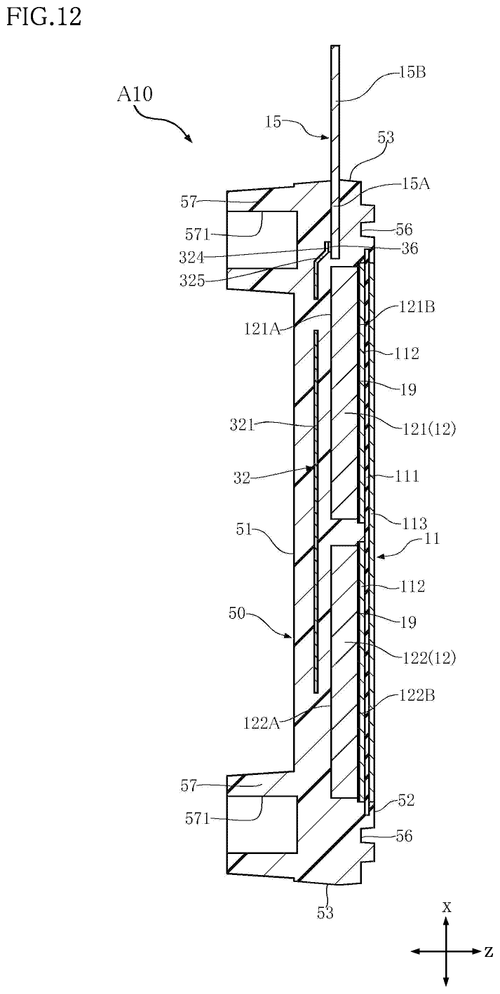

As shown in FIGS. 2 and 3, the support member 11 is located opposite to the semiconductor elements 21 with the support layer 12 interposed therebetween in the thickness direction z. The support member 11 supports the support layer 12. In the semiconductor device A10, the support member 11 is provided by a DBC (Direct Bonded Copper) substrate. As shown in FIGS. 12 to 17, the support member 11 includes an insulating layer 111, an intermediate layer 112, and a heat dissipation layer 113. The support member 11 is covered with the sealing resin 50 except a part of the heat dissipation layer 113.

As shown in FIGS. 12 to 17, the insulating layer 111 includes portions interposed between the intermediate layer 112 and the heat dissipation layer 113 in the thickness direction z. The insulating layer 111 is made of a material with relatively high thermal conductivity. The insulating layer 111 may be made of ceramics containing aluminum nitride (AlN), for example. The insulating layer 111 may be made of a sheet of insulating resin rather than ceramics. The thickness of the insulating layer 111 is smaller than that of the support layer 12.

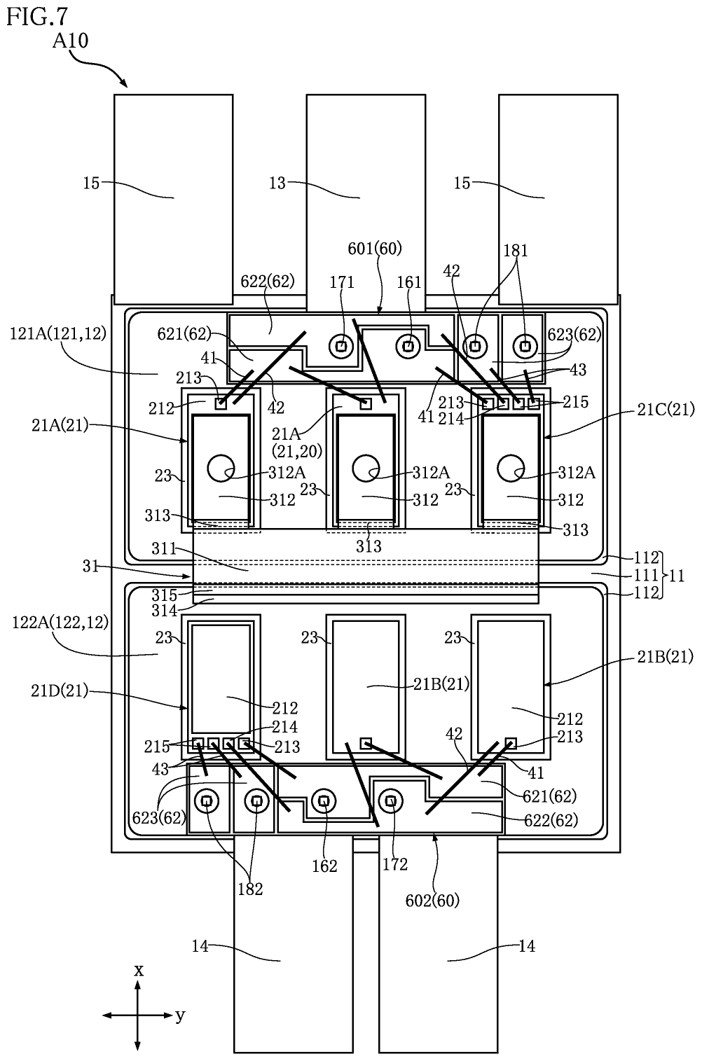

As shown in FIGS. 12 to 17, the intermediate layer 112 is located on one side of the insulating layer 111 in the thickness direction z. The intermediate layer 112 includes a pair of regions spaced apart from each other in the first direction x. The composition of the intermediate layer 112 includes copper (Cu). That is, the intermediate layer 112 contains copper. As shown in FIG. 7, the intermediate layer 112 is surrounded by the periphery of the insulating layer 111 as viewed in the thickness direction z.

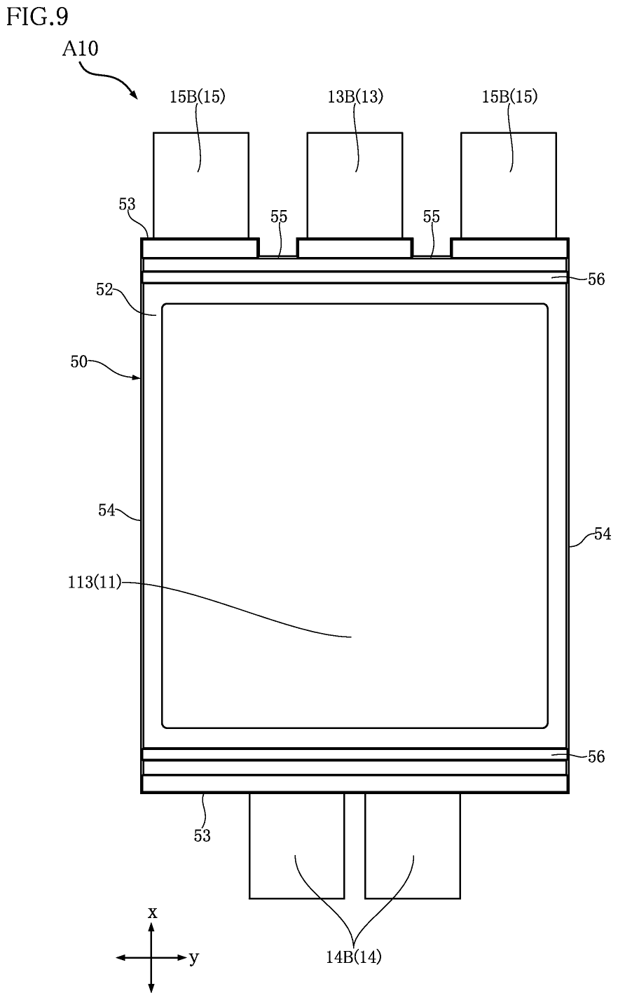

As shown in FIGS. 12 to 17, the heat dissipation layer 113 is located opposite to the intermediate layer 112 and the support layer 12 with the insulating layer 111 interposed therebetween in the thickness direction z. As shown in FIG. 9, the heat dissipation layer 113 is exposed from the sealing resin 50. A heat sink (not shown) is bonded to the heat dissipation layer 113. The composition of the heat dissipation layer 113 includes copper. The thickness of the heat dissipation layer 113 is larger than that of the insulating layer 111. The heat dissipation layer 113 is surrounded by the periphery of the insulating layer 111 as viewed in the thickness direction z.

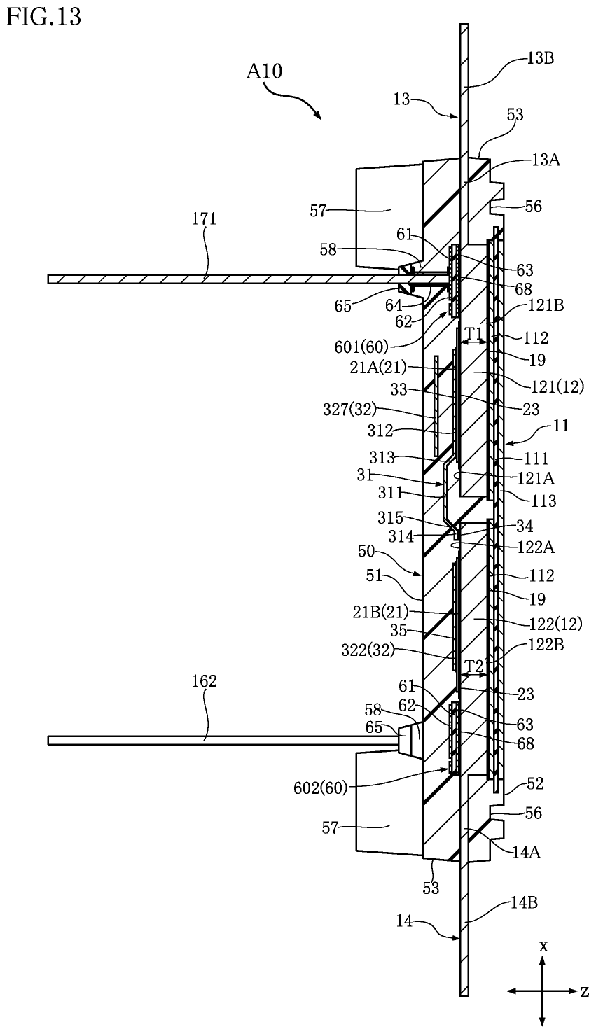

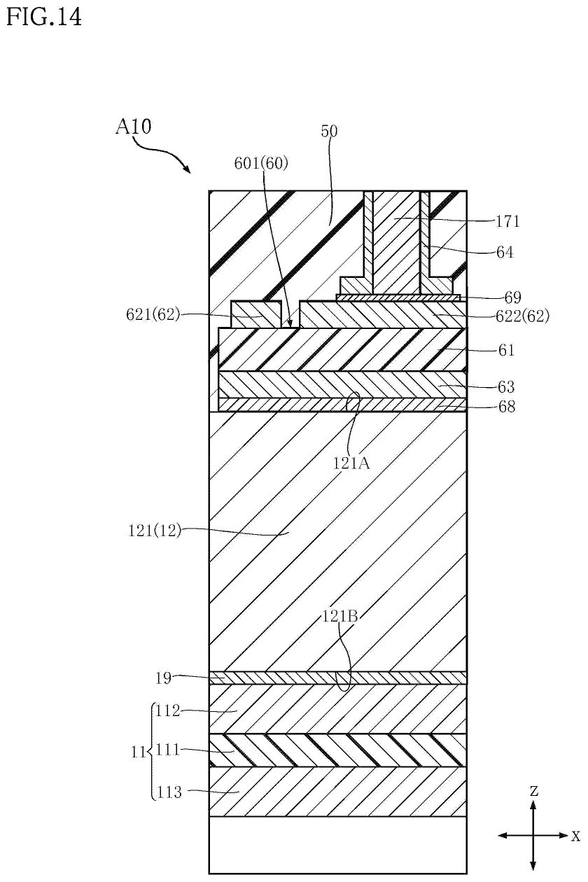

As shown in FIGS. 2 and 3, the support layer 12 is bonded to the support member 11. The support layer 12 contains a metal element. The metal element is copper. Thus, the support layer 12 has electrical conductivity. The support layer 12 includes a first support layer 121 and a second support layer 122 spaced apart from each other in the first direction x. As shown in FIGS. 12 and 13, the first support layer 121 has a first obverse surface 121A and a first reverse surface 121B facing away from each other in the thickness direction z. The first obverse surface 121A faces the semiconductor elements 21. As shown in FIG. 14, the first reverse surface 121B is bonded to one of the pair of regions of the intermediate layer 112 via a first adhesive layer 19. The first adhesive layer 19 may be a brazing material including e.g. silver (Ag) in its composition. As shown in FIGS. 12 and 13, the second support layer 122 has a second obverse surface 122A and a second reverse surface 122B facing away from each other in the thickness direction z. The second obverse surface 122A faces the same side as the first obverse surface 121A in the thickness direction z. The second reverse surface 122B is bonded to the other one of the pair of regions of the intermediate layer 112 via the first adhesive layer 19.

As shown in FIGS. 3 and 7, the semiconductor elements 21 are mounted on the support layer 12. The semiconductor elements 21 are MOSFETs (Metal-Oxide-Semiconductor Field-Effect Transistor), for example. Alternatively, the semiconductor elements 21 may be switching elements, such as IGBTs (Insulated Gate Bipolar Transistor) or diodes. In the semiconductor device A10 described herein, the semiconductor elements 21 are n-channel MOSFETs of a vertical structure type. The semiconductor elements 21 include a compound semiconductor substrate. The composition of the compound semiconductor substrate includes silicon carbide (SiC).

As shown in FIG. 7, in the semiconductor device A10, the plurality of semiconductor elements 21 include two first elements 21A, two second elements 21B, a third element 21C, and a fourth element 21D. The structure of the two second elements 21B is the same as the structure of the two first elements 21A. The structure of the fourth element 21D is the same as the structure of the third element 21C. The two first elements 21A and the third element 21C are mounted on the first obverse surface 121A of the first support layer 121. The two first elements 21A and the third element 21C are arranged side by side in the second direction y. The two second elements 21B and the fourth element 21D are mounted on the second obverse surface 122A of the second support layer 122. The two second element 21B and the fourth element 21D are arranged side by side in the second direction y.

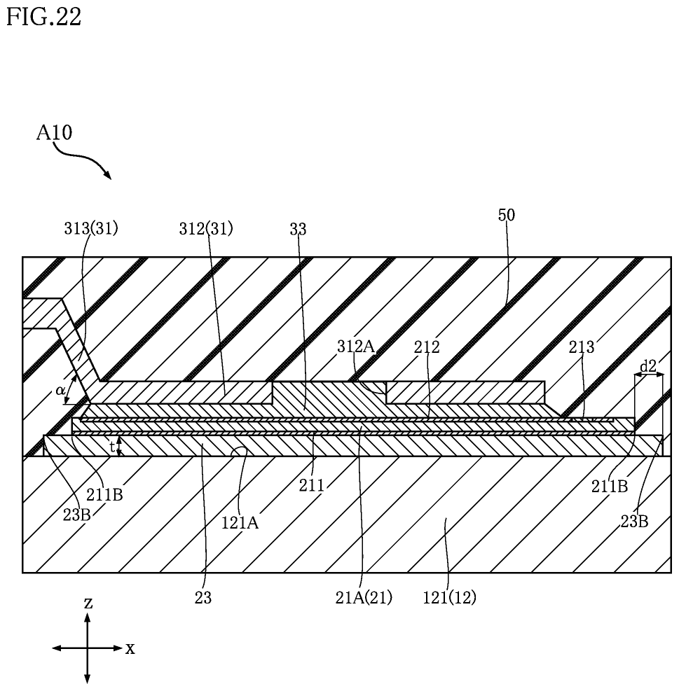

As shown in FIG. 22, each of the semiconductor elements 21 has an element metal layer 211, a first electrode 212, and a second electrode 213.

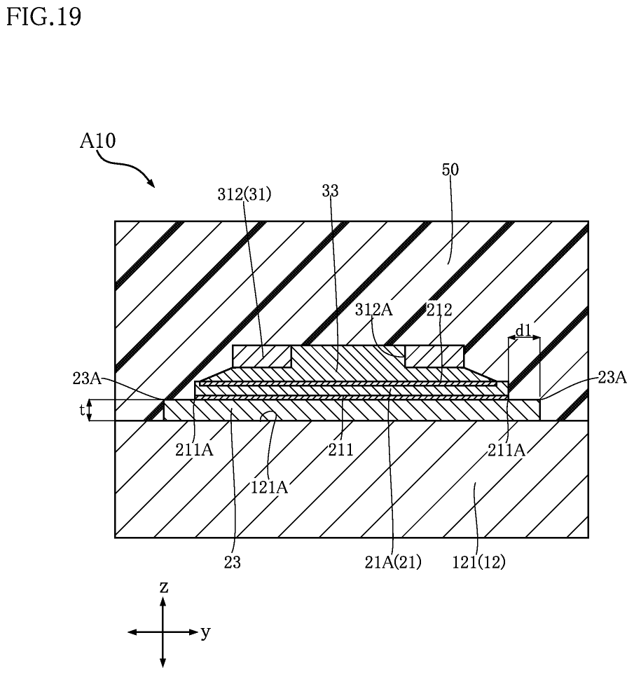

As shown in FIGS. 19 and 22, the element metal layer 211 faces the support layer 12. In the semiconductor device A10, the element metal layer 211 is electrically connected to a circuit provided in the semiconductor element 21. Thus, the element metal layer 211 corresponds to an electrode of the semiconductor element 21. Alternatively, as in a switching element of a vertical structure type, the element metal layer 211 may not correspond to an electrode of the semiconductor element 21. In such a case, the support layer 12 does not constitute a conduction path related to the semiconductor element 21. A current corresponding to the electric power before being converted by the semiconductor element 21 flows in the element metal layer 211. That is, the element metal layer 211 corresponds to the drain electrode of the semiconductor element 21.

As shown in FIGS. 19 and 22, the first electrode 212 is located opposite to the element metal layer 211 in the thickness direction z. A current corresponding to the electric power after being converted by the semiconductor element 21 flows in the first electrode 212. That is, the first electrode 212 corresponds to the source electrode of the semiconductor element 21.

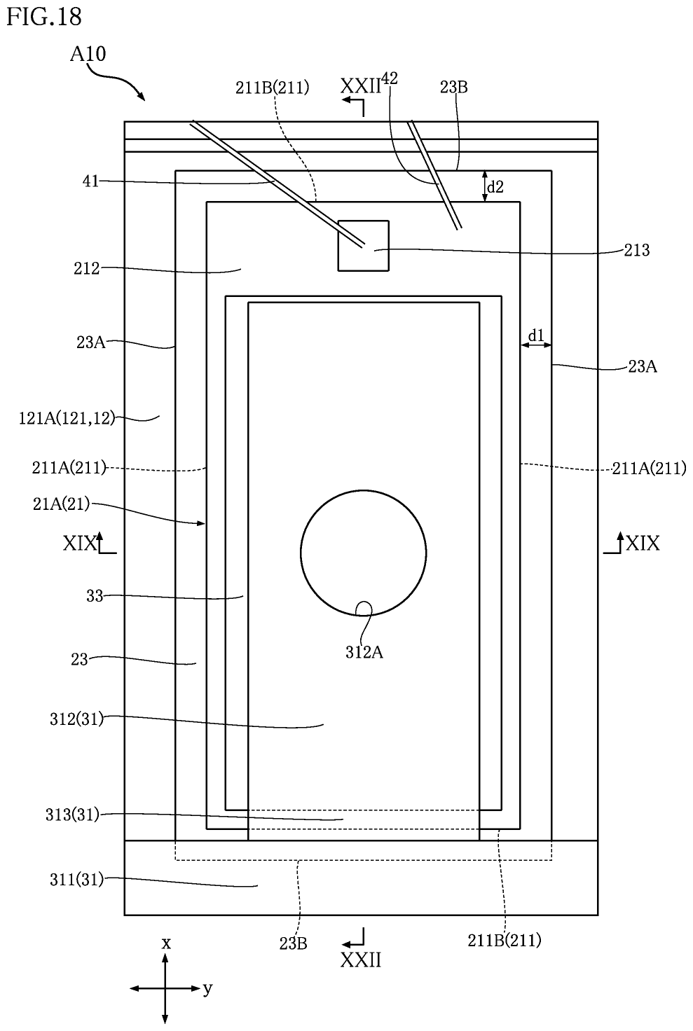

As shown in FIGS. 18 and 22, the second electrode 213 is located on the same side as the first electrode 212 in the thickness direction z. A gate voltage for driving the semiconductor element 21 is applied to the second electrode 213. That is, the second electrode 213 corresponds to the gate electrode of the semiconductor element 21. As viewed in the thickness direction z, the area of the second electrode 213 is smaller than that of the first electrode 212.

As shown in FIG. 7, each of the third element 21C and the fourth element 21D further includes a third electrode 214 and a pair of fourth electrodes 215. The current flowing in the third electrode 214 of the third element 21C is the same as the current flowing in the first electrode 212 of the third element 21C. The current flowing in the third electrode 214 of the fourth element 21D is the same as the current flowing in the first electrode 212 of the fourth element 21D.

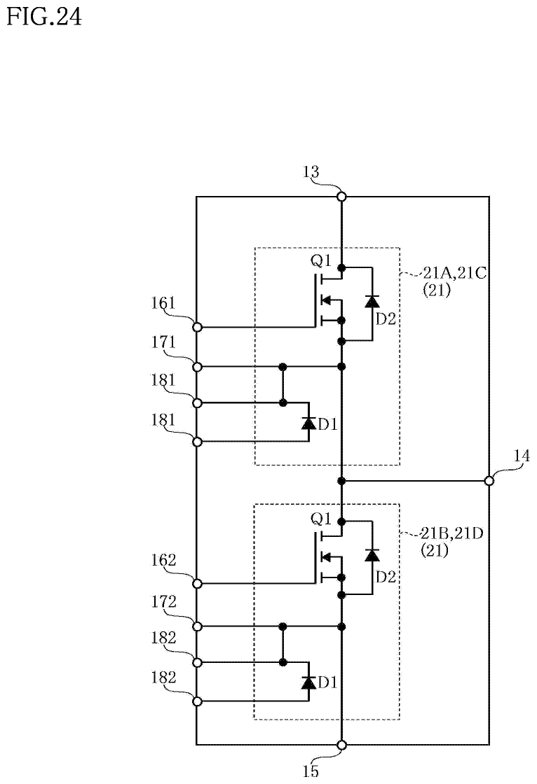

As shown in FIG. 24, a half-bridge switching circuit is formed in the semiconductor device A20. The two first elements 21A and the third element 21C form an upper arm circuit of the switching circuit. In the upper arm circuit, the two first elements 21A and the third element 21C are connected in parallel with each other. The two second elements 21B and the fourth element 21D form a lower arm circuit of the switching circuit. In the lower arm circuit, the two second elements 21B and the fourth element 21D are connected in parallel with each other.

As shown in FIG. 24, each of the semiconductor elements 21 includes a switching function section Q1 and a freewheeling diode D2. Each of the third element 21C and the fourth element 21D further includes a diode function section D1. The pair of fourth electrodes 215 are electrically connected to the diode function section D1.

As shown in FIGS. 19 and 22, each of the joining layers 23 is interposed between the support layer 12 and the element metal layer 211 of one of the semiconductor elements 21. In the semiconductor device A10, the composition of the joining layers 23 includes aluminum (Al). The Vickers hardness of the joining layers 23 is lower than that of the support layer 12.

In the semiconductor device A10, the element metal layers 211 of the semiconductor elements 21 are bonded to the support layer 12 via the joining layers 23 by solid-phase diffusion. Thus, the element metal layers 211 of the two first elements 21A and the third element 21C are electrically connected to the first support layer 121. The element metal layers 211 of the second elements 21B and the fourth element 21D are electrically connected to the second support layer 122. Bonding by solid-phase diffusion needs to be performed under high temperature and high pressure conditions.

As shown in FIG. 21, a solid-phase diffusion bonding layer 24 interposes between the support layer 12 and the element metal layer 211 of each semiconductor element 21. The solid-phase diffusion bonding layer 24 may be considered as a metallic bond region located at the interface between two mutually-contacting metal layers as a result of bonding these metal layers by solid-phase diffusion. Therefore, the solid-phase diffusion bonding layer 24 does not necessarily exist as a metallic bond layer with a definitely significant thickness. In an embodiment, the solid-phase diffusion bonding layer 24 may be observed as an area produced along the interface between the two metal layers, in which impurities or voids, diffused in during the solid-phase diffusion bonding process, remain.

As shown in FIG. 21, each solid-phase diffusion bonding layer 24 includes a first bonding layer 241 and a second bonding layer 242 spaced apart from each other in the thickness direction z. The first bonding layer 241 is located between the support layer 12 and a joining layer 23. In the semiconductor device A10, the first bonding layer 241 is located at the interface between the support layer 12 and the joining layer 23. The second bonding layer 242 is located between the joining layer 23 and the element metal layer 211 of one of the semiconductor elements 21. In the semiconductor device A10, the second bonding layer 242 is located at the interface between the joining layer 23 and the element metal layer 211.

As shown in FIGS. 18, 19 and 22, the element metal layer 211 of each semiconductor element 21 has a first edge 211A and a third edge 211B. The first edge 211A and the third edge 211B are included in the periphery of the element metal layer 211. The first edge 211A extends in the first direction x. The first edge 211A includes a pair of sections spaced apart from each other in the second direction y. The third edge 211B extends in the second direction y. The third edge 211B includes a pair of sections spaced apart from each other in the first direction x.

As shown in FIGS. 18, 19 and 22, each joining layer 23 has a second edge 23A and a fourth edge 23B. The second edge 23A and the fourth edge 23B are included in the periphery of the joining layer 23. The second edge 23A is located closest to the first edge 211A of the element metal layer 211 and extends in the first direction x. The second edge 23A includes a pair of sections spaced apart from each other in the second direction y. The fourth edge 23B is located closest to the third edge 211B of the element metal layer 211 and extends in the second direction y. The fourth edge 23B includes a pair of sections spaced apart from each other in the first direction x.

The distance d1 and the distance d2 shown in FIG. 18 will be described. The distance d1 is the distance from the first edge 211A of the element metal layer 211 to the second edge 23A of the joining layer 23 in the second direction y. The distance d2 is the distance from the third edge 211B of the element metal layer 211 to the fourth edge 23B of the joining layer 23 in the first direction x. When the second edge 23A is spaced apart from the element metal layer 211 as viewed in the thickness direction z, the value of the distance d1 is positive. When the second edge 23A overlaps with the element metal layer 211 as viewed in the thickness direction z, the value of the distance d1 is 0 or negative. As with the distance d1, the value of the distance d2 is positive when the fourth edge 23B is spaced apart from the element metal layer 211 as viewed in the thickness direction z. When the fourth edge 23B overlaps with the element metal layer 211 as viewed in the thickness direction z, the value of the distance d2 is 0 or negative.

When the value of the distance d1 is positive, then 0<d1≤2 t. That is, the magnitude of d1 (=|d1|) is equal to or less than twice the thickness t. When the value of the distance d1 is 0 or negative (i.e., non-positive), then −t≤d1≤0. That is, the magnitude of d1 (=|d1|) is equal to or less than the thickness t. In other words, the magnitude of d1 is equal to or less than 2 t (|d1|≤2 t) whether the value of the distance d1 is positive or non-positive, and in particular, the magnitude of d1 is equal to or less than t (|d1|t) when the value of the distance d1 is non-positive. Herein, the thickness t is equal to or less than 0.3 mm and typically 0.2 mm. Such a relationship also holds for the distance d2. In the semiconductor device A10, both of 0<d1≤2 t and 0<d2≤2 t hold. Therefore, as viewed in the thickness direction z, the periphery of the joining layer 23 including the second edge 23A and the fourth edge 23B surrounds the periphery of the element metal layer 211 including the first edge 211A and the third edge 211B.

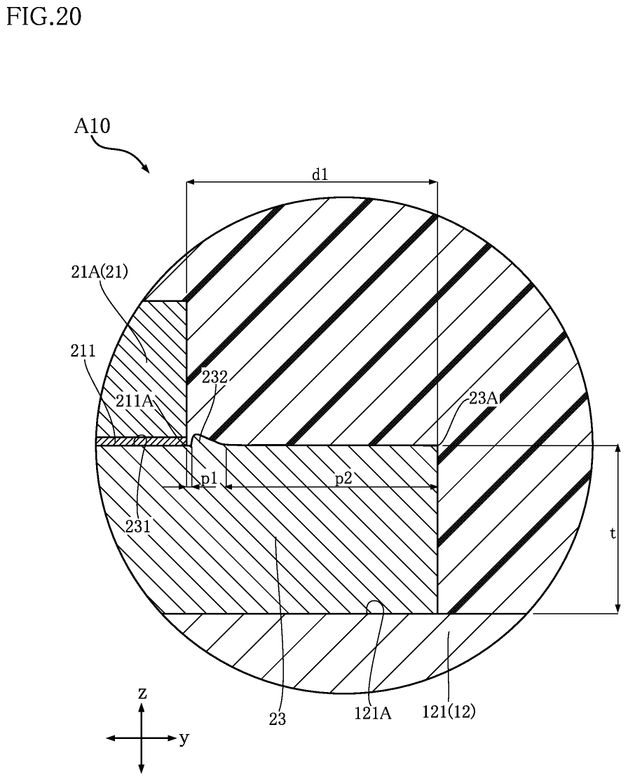

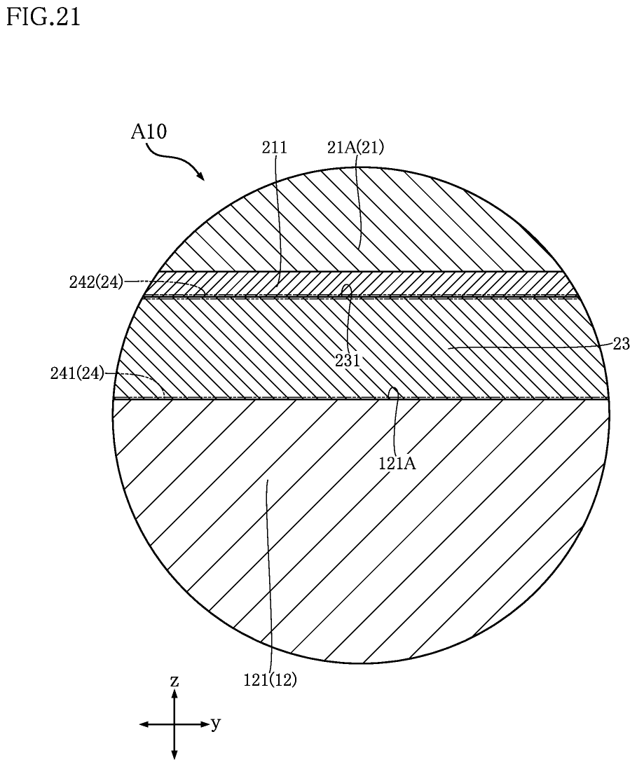

As shown in FIG. 20, each joining layer 23 has a joining surface 231 that faces the element metal layer 211 of a semiconductor element 21. The joining layer 23 is formed with a protrusion 232 that protrude from the joining surface 231 in the thickness direction z. As shown in FIG. 20, in the second direction y, the protrusion 232 is located between the first edge 211A of the element metal layer 211 and the second edge 23A of the joining layer 23. The pitch p1 between the first edge 211A and the protrusion 232 in the second direction y is shorter than the pitch p2 between the protrusion 232 and the second edge 23A of the joining layer 23 in the second direction y.

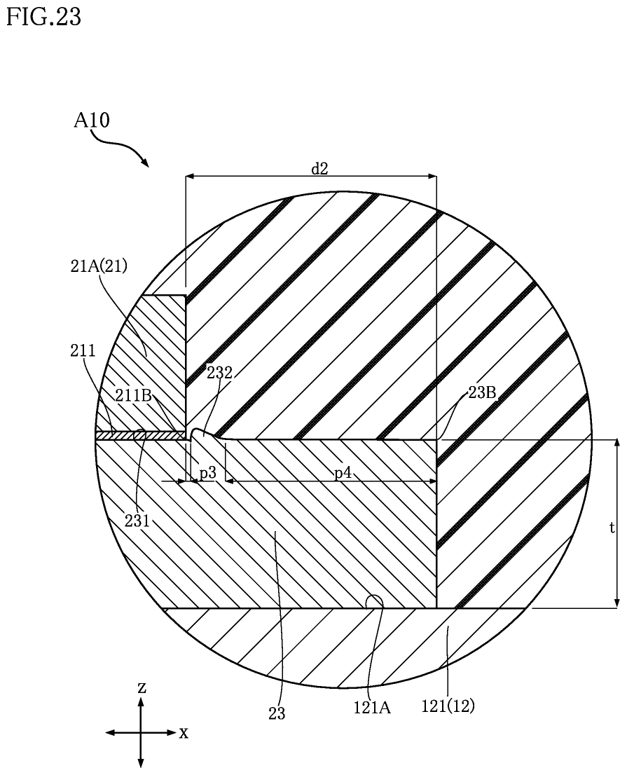

As shown in FIG. 23, in the first direction x, the protrusion 232 is located between the third edge 211B of the element metal layer 211 and the fourth edge 23B of the joining layer 23. The pitch p3 between the third edge 211B and the protrusion 232 in the first direction x is shorter than the pitch p4 between the protrusion 232 and the fourth edge 23B in the first direction x.

As shown in FIGS. 5 and 13, the first input terminal 13 is located on one side of the support layer 12 in the first direction and connected to the first support layer 121. Thus, the first input terminal 13 is electrically connected to the element metal layers 211 of the two first elements 21A and the third element 21C via the first support layer 121. The first input terminal 13 is a P terminal (positive electrode) to which a DC power supply voltage to be converted is applied. The first input terminal 13 extends from the first support layer 121 in the first direction x. The first input terminal 13 has a covered portion 13A and an exposed portion 13B. As shown in FIG. 13, the covered portion 13A is connected to the first support layer 121 and covered with the sealing resin 50. The covered portion 13A is flush with the first obverse surface 121A of the first support layer 121. The exposed portion 13B extends from the covered portion 13A in the first direction x and is exposed from the sealing resin 50. The thickness of the first input terminal 13 is smaller than that of the first support layer 121.

As shown in FIGS. 5 and 13, the output terminal 14 is located opposite to the first input terminal 13 with respect to the support layer 12 in the first direction x and connected to the second support layer 122. Thus, the output terminal 14 is electrically connected to the element metal layers 211 of the two second elements 21B and the fourth element 21D via the second support layer 122. The AC power converted by the semiconductor elements 21 is outputted from the output terminal 14. The output terminal 14 includes a pair of regions spaced apart from each other in the second direction y. The output terminal 14 has a covered portion 14A and an exposed portion 14B. As shown in FIG. 13, the covered portion 14A is connected to the second support layer 122 and covered with the sealing resin 50. The covered portion 14A is flush with the second obverse surface 122A of the second support layer 122. The exposed portion 14B extends from the covered portion 14A in the first direction x and is exposed from the sealing resin 50. The thickness of the output terminal 14 is smaller than that of the second support layer 122.

As shown in FIGS. 5 and 12, the second input terminal 15 is located on the same side as the first input terminal 13 with respect to the support layer 12 in the first direction x and spaced apart from the support layer 12. The second input terminal 15 is electrically connected to the first electrodes 212 of the two second elements 21B and the fourth element 21D. The second input terminal 15 is an N terminal (negative electrode) to which a DC power supply voltage to be converted is applied. The second input terminal 15 includes a pair of regions spaced apart from each other in the second direction y. The first input terminal 13 is located between the pair of regions in the second direction y. The second input terminal 15 has a covered portion 15A and an exposed portion 15B. As shown in FIG. 12, the covered portion 15A is spaced apart from the first support layer 121 and covered with the sealing resin 50. The exposed portion 15B extends from the covered portion 15A in the first direction x and is exposed from the sealing resin 50.

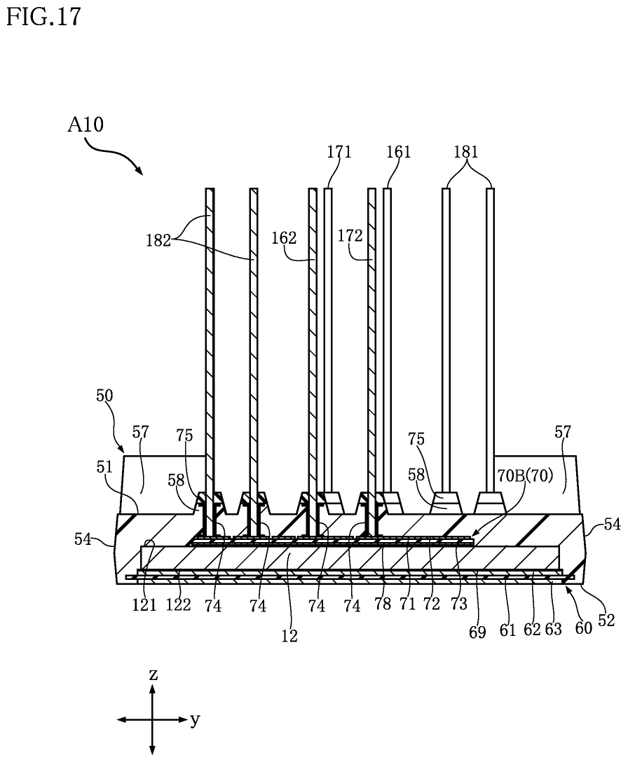

The pair of control wirings 60 form a part of the conduction path between the semiconductor elements 21 and the first gate terminal 161, the second gate terminal 162, the first detection terminal 171, the second detection terminal 172, the pair of first diode terminals 181, the pair of second diode terminals 182. As shown in FIGS. 5 to 7, the pair of control wirings 60 include a first wiring 601 and a second wiring 602. The first wiring 601 is located between the first and the third elements 21A and 21C and the first and the second input terminals 13 and 15 in the first direction x. The first wiring 601 is bonded to the first obverse surface 121A of the first support layer 121. The second wiring 602 is located between the second and the fourth elements 21B and 21D and the output terminal 14 in the first direction x. The second wiring 602 is bonded to the second obverse surface 122A of the second support layer 122. As shown in FIGS. 13 and 17, the control wirings 60 include an insulating layer 61, a plurality of wiring layers 62, a metal layer 63, a plurality of holders 64, and a plurality of covering layers 65. The control wirings 60 are covered with the sealing resin 50 except a part of each holder 64 and the covering layers 65.

As shown in FIG. 14, the insulating layer 61 includes a portion interposed between the wiring layers 62 and the metal layer 63 in the thickness direction z. The insulating layer 61 is made of ceramics, for example. The insulating layer 61 may be made of a sheet of insulating resin rather than ceramics.

As shown in FIG. 14, the wiring layers 62 are located on one side of the insulating layer 61 in the thickness direction z. The composition of the wiring layers 62 includes copper. As shown in FIG. 7, the wiring layers 62 include a first wiring layer 621, a second wiring layer 622, and a pair of third wiring layers 623. As viewed in the thickness direction z, the area of each of the third wiring layers 623 is smaller than the area of each of the first wiring layer 621 and the second wiring layer 622.

As shown in FIG. 14, the metal layer 63 is located opposite to the wiring layers 62 with the insulating layer 61 interposed therebetween in the thickness direction z. The composition of the metal layer 63 includes copper. The metal layer 63 of the first wiring 601 is bonded to the first obverse surface 121A of the first support layer 121 with a second adhesive layer 68. The metal layer 63 of the second wiring 602 is bonded to the second obverse surface 122A of the second support layer 122 with a second adhesive layer 68. The second adhesive layer 68 may be made of a material having electrical conductivity or a material that does not have electrical conductivity. The second adhesive layer 68 may be solder, for example.

As shown in FIG. 14, the holders 64 are individually bonded to the wiring layers 62 with third adhesive layers 69. The holders are made of a conductive material, such as metal. Each of the holders 64 has a cylindrical shape extending along the thickness direction z. One end of each holder 64 is bonded to a relevant wiring layer 62. The other end of each holder 64 is exposed from the sealing resin 50. The third adhesive layers 69 have electrical conductivity. The third adhesive layers 69 may be solder, for example.

As shown in FIGS. 13 and 17, each of the covering layers 65 covers a part of a holder 64 that is exposed from the sealing resin 50. The covering layers 65 are individually disposed on second projections 58, described later, of the sealing resin 50. The covering layers 65 have an electrically insulating property. The covering layers 65 are made of a material containing resin, for example.

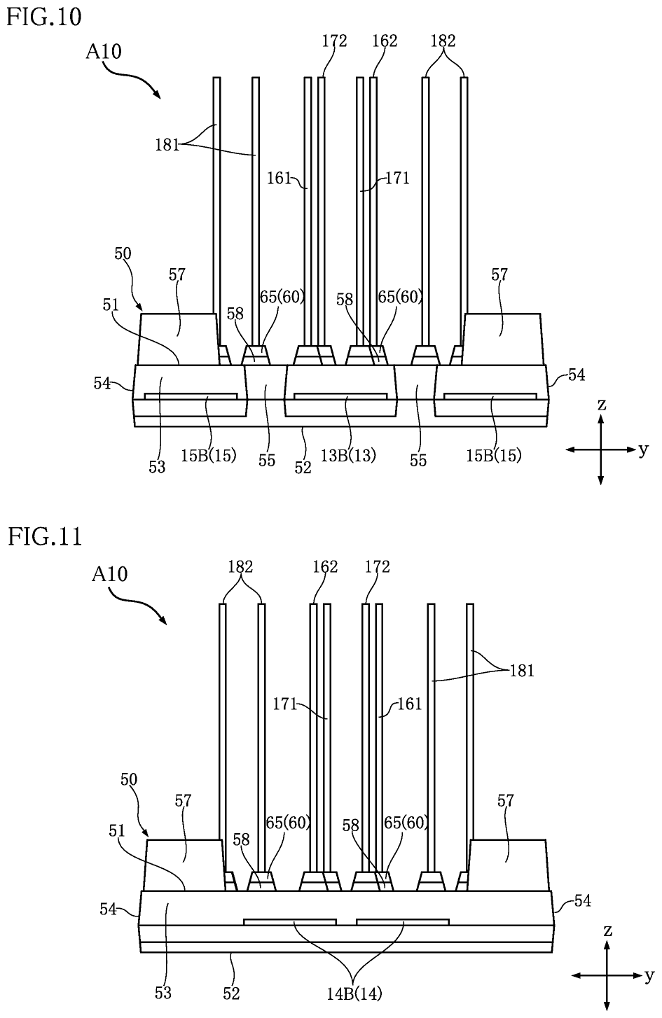

As shown in FIGS. 1 to 3, the first gate terminal 161, the second gate terminal 162, the first detection terminal 171, the second detection terminal 172, the pair of first diode terminals 181 and the pair of second diode terminals 182 are made of metal pins extending in the thickness direction z. These terminals are individually press-fitted into the holders 64 of the control wirings 60. Thus, these terminals are supported by the holders 64. As shown in FIGS. 10, 11 and 17, each of these terminals is partially covered with one of the covering layers 65 of the control wirings 60.

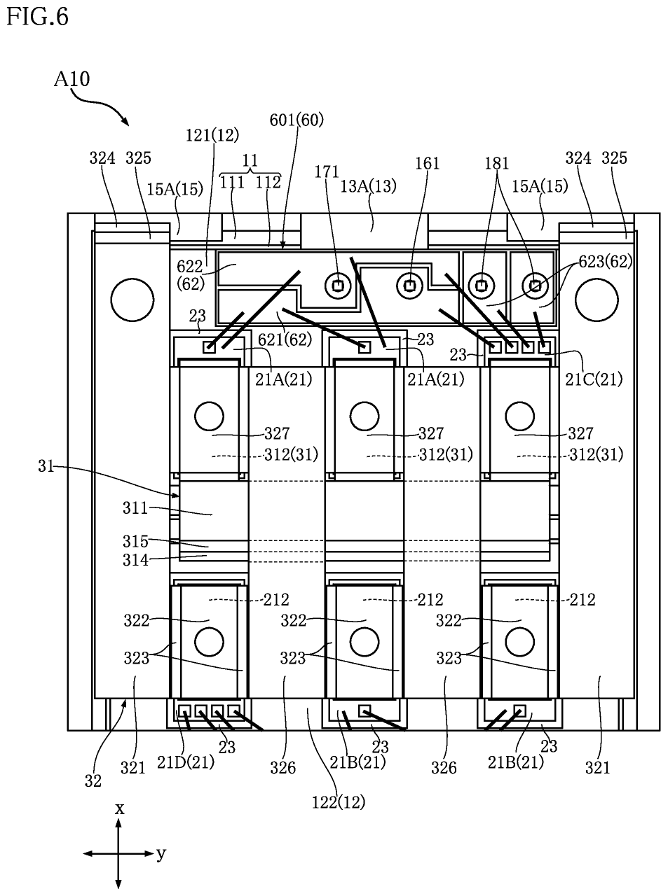

As shown in FIG. 6, the first gate terminal 161 is press-fitted into the holder 64 bonded to the first wiring layer 621 of the first wiring 601 of the control wirings 60. Thus, the first gate terminal 161 is supported by the holder 64 and electrically connected to the first wiring layer 621 of the first wiring 601. The first gate terminal 161 is also electrically connected to the second electrodes 213 of the two first elements 21A and the third element 21C. A gate voltage for driving the two first elements 21A and the third element 21C is applied to the first gate terminal 161.

As shown in FIGS. 6 and 14, the first detection terminal 171 is press-fitted into the holder 64 bonded to the second wiring layer 622 of the first wiring 601 of the control wirings 60. Thus, the first detection terminal 171 is supported by the holder 64 and electrically connected to the second wiring layer 622 of the first wiring 601. The first detection terminal 171 is also electrically connected to the first electrode 212 of the two first elements 21A and the third electrode 214 of the third element 21C. To the first detection terminal 171 is applied a voltage corresponding to the current that is the highest of the currents flowing in the respective first electrodes 212 of the two first elements 21A and the current flowing in the third electrode 214 of the third element 21C.

As shown in FIG. 6, the pair of first diode terminals 181 are individually press-fitted into the pair of holders 64 bonded to the pair of third wiring layers 623 of the first wiring 601 of the control wirings 60. Thus, the pair of first diode terminals 181 are supported by the pair of holders 64 and electrically connected to the pair of third wiring layers 623 of the first wiring 601. The pair of first diode terminals 181 are also electrically connected to the pair of fourth electrodes 215 of the third element 21C.

As shown in FIGS. 7 and 17, the second gate terminal 162 is press-fitted into the holder 64 bonded to the first wiring layer 621 of the second wiring 602 of the control wirings 60. Thus, the second gate terminal 162 is supported by the holder 64 and electrically connected to the first wiring layer 621 of the second wiring 602. The second gate terminal 162 is also electrically connected to the second electrodes 213 of the two second elements 21B and the fourth element 21D. A gate voltage for driving the two second elements 21B and the fourth element 21D is applied to the second gate terminal 162.

As shown in FIGS. 7 and 17, the second detection terminal 172 is press-fitted into the holder 64 bonded to the second wiring layer 622 of the second wiring 602 of the control wirings 60. Thus, the second detection terminal 172 is supported by the holder 64 and electrically connected to the second wiring layer 622 of the second wiring 602. The second detection terminal 172 is also electrically connected to the first electrodes 212 of the two second elements 21B and the third electrode 214 of the fourth element 21D. To the second detection terminals 172 is applied a voltage corresponding to the current that is the highest of the currents flowing in the respective first electrodes 212 of the two second elements 21B and the current flowing in the third electrode 214 of the fourth element 21D.

As shown in FIGS. 7 and 17, the pair of second diode terminals 182 are individually press-fitted into the pair of holders 64 bonded to the pair of third wiring layers 623 of the second wiring 602 of the control wirings 60. Thus, the pair of second diode terminals 182 are supported by the pair of holders 64 and electrically connected to the pair of third wiring layers 623 of the second wiring 602. The pair of second diode terminals 182 are also electrically connected to the pair of fourth electrodes 215 of the fourth element 21D.

As shown in FIG. 7, gate wires 41 are bonded to the second electrodes 213 of the two first elements 21A and the third element 21C, and the first wiring layer 621 of the first wiring 601. With such a configuration, the first gate terminal 161 is electrically connected to the second electrodes 213 of the two first elements 21A and the third element 21C. As shown in FIG. 7, gate wires 41 are also bonded to the second electrodes 213 of the two second elements 21B and the fourth element 21D, and the first wiring layer 621 of the second wiring 602. With such a configuration, the second gate terminal 162 is electrically connected to the second electrodes 213 of the two second elements 21B and the fourth element 21D. The composition of the gate wires 41 includes gold (Au). Alternatively, the composition of the gate wires 41 may include copper or aluminum.

As shown in FIG. 7, detection wires 42 are bonded to the first electrodes 212 of the two first elements 21A, the third electrode 214 of the third element 21C, and the second wiring layer 622 of the first wiring 601. With such a configuration, the first detection terminal 171 is electrically connected to the first electrodes 212 of the two first elements 21A and the third electrode 214 of the third element 21C. As shown in FIG. 7, detection wires 42 are also bonded to the first electrodes 212 of the two second elements 21B, the third electrode 214 of the fourth element 21D, and the second wiring layer 622 of the second wiring 602. With such a configuration, the second detection terminal 172 is electrically connected to the first electrodes 212 of the two second elements 21B and the third electrode 214 of the fourth element 21D. The composition of the detection wires 42 includes gold. Alternatively, the composition of the detection wires 42 may include copper or aluminum.

As shown in FIG. 7, the diode wires 43 are individually bonded to the pair of fourth electrodes 215 of the third element 21C and the pair of third wiring layers 623 of the first wiring 601. With such a configuration, the pair of first diode terminals 181 are electrically connected to the pair of fourth electrodes 215 of the third element 21C. As shown in FIG. 7, the diode wires 43 are also individually bonded to the pair of fourth electrodes 215 of the fourth element 21D and the pair of third wiring layers 623 of the second wiring 602. With such a configuration, the pair of second diode terminals 182 are electrically connected to the pair of fourth electrodes 215 of the fourth element 21D. The composition of the diode wires 43 includes gold. Alternatively, the composition of the diode wires 43 may include copper or aluminum.

As shown in FIG. 7, the first conductive member 31 is bonded to the first electrodes 212 of the two first elements 21A, the first electrode 212 of the third element 21C, and the second obverse surface 122A of the second support layer 122. Thus, the first electrodes 212 of the two first elements 21A and the first electrode 212 of the third element 21C are electrically connected to the second support layer 122. The composition of the first conductive member 31 includes copper. The first conductive member 31 is a metal clip. The first conductive member 31 has a main body 311, a plurality of first bond portions 312, a plurality of first connecting portions 313, a second bond portion 314, and a second connecting portion 315.

The main body 311 is a main part of the first conductive member 31. As shown in FIG. 7, the main body 311 extends in the second direction y. As shown in FIG. 13, the main body 311 bridges the gap between the first support layer 121 and the second support layer 122.

As shown in FIGS. 7, 18 and 19, the first bond portions 312 are individually bonded to the first electrodes 212 of the two first elements 21A and the third element 21C. Each of the first bond portions 312 faces the first electrode 212 of one of the two first elements 21A and the third element 21C. The first bond portions 312 are formed with openings 312A penetrating in the thickness direction z.

As shown in FIG. 7, the first connecting portions 313 are connected to the main body 311 and the first bond portions 312. The first connecting portions 313 are spaced apart from each other in the second direction y. As shown in FIG. 13, as viewed in the second direction y, the first connecting portions 313 are inclined to become farther away from the first obverse surface 121A of the first support layer 121 as proceeding from the first bond portions 312 toward the main body 311. As viewed in the second direction y, the acute angle α (see FIG. 22) formed by the first connecting portions 313 with respect to the first bond portions 312 is equal to or greater than 30° and equal to or less than 60°.

As shown in FIGS. 7 and 13, the second bond portion 314 is bonded to the second obverse surface 122A of the second support layer 122. The second bond portion 314 faces the second obverse surface 122A. The second bond portion 314 extends in the second direction y. The dimension of the second bond portion 314 in the second direction y is equal to the dimension of the main body 311 in the second direction y.

As shown in FIGS. 7 and 13, the second connecting portion 315 is connected to the main body 311 and the second bond portion 314. As viewed in the second direction y, the second connecting portion 315 is inclined to become farther away from the second obverse surface 122A of the second support layer 122 as proceeding from the second bond portion 314 toward the main body 311. The dimension of the second connecting portion 315 in the second direction y is equal to the dimension of the main body 311 in the second direction y.

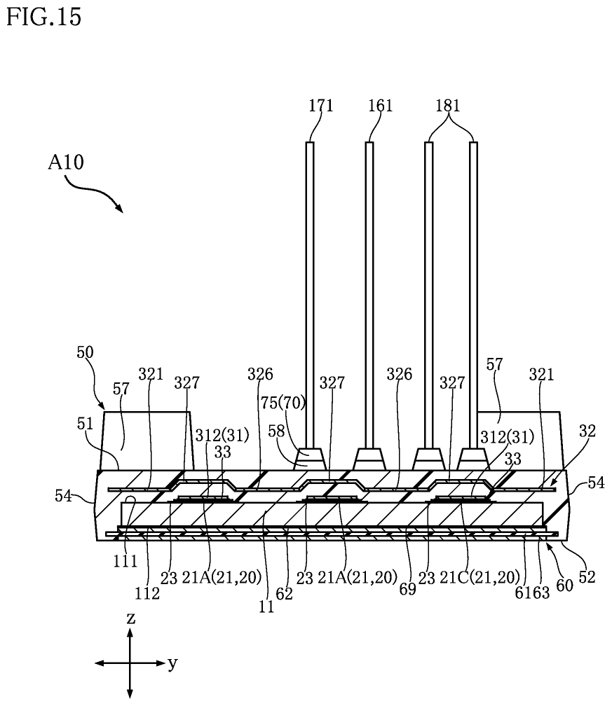

As shown in FIGS. 15, 18, 19 and 22, the semiconductor device A10 further includes a first conductive joining layer 33. The first conductive joining layer 33 is interposed between the first electrodes 212 of the two first elements 21A and the third element 21C, and the first bond portions 312. A portion of the first conductive joining layer 33 is located within the openings 312A of the first bond portions 312. The first conductive joining layer 33 conductively bonds the first electrodes 212 of the two first elements 21A and the third element 21C to the first bond portions 312. The first conductive joining layer 33 may be solder, for example. Alternatively, the first conductive joining layer 33 may contain sintered metal particles.

As shown in FIG. 13, the semiconductor device A10 further includes a second conductive joining layer 34. The second conductive joining layer 34 is interposed between the second obverse surface 122A of the second support layer 122 and the second bond portion 314. The second conductive joining layer 34 conductively bonds the second obverse surface 122A and the second bond portion 314 to each other. The second conductive joining layer 34 may be solder, for example. Alternatively, the second conductive joining layer 34 may contain sintered metal particles.

As shown in FIG. 6, the second conductive member 32 is bonded to the first electrodes 212 of the two second elements 21B, the first electrode 212 of the fourth element 21D, and the covered portion 15A of the second input terminal 15. Thus, the first electrodes 212 of the two second elements 21B and the first electrode 212 of the fourth element 21D are electrically connected to the second input terminal 15. The composition of the second conductive member 32 includes copper. The second conductive member 32 is a metal clip. The second conductive member 32 has a pair of main bodies 321, a plurality of third bond portions 322, a plurality of third connecting portions 323, a pair of fourth bond portions 324, a pair of fourth connecting portions 325, a pair of intermediate portions 326, and a plurality of beam portions 327.

As shown in FIG. 6, the pair of main bodies 321 are spaced apart from each other in the second direction y. The main bodies 321 extend in the first direction x. As shown in FIG. 12, the main bodies 321 are disposed in parallel to the first obverse surface 121A of the first support layer 121 and the second obverse surface 122A of the second support layer 122. The main bodies 321 are located farther from the first obverse surface 121A and the second obverse surface 122A than is the main body 311 of the first conductive member 31.

As shown in FIG. 6, the pair of intermediate portions 326 are spaced apart from each other in the second direction y and located between the pair of main bodies 321 in the second direction y. The intermediate portions 326 extend in the first direction x. The dimension of each of the intermediate portions 326 in the first direction x is smaller than the dimension of each main body 321 in the first direction x. As viewed in the thickness direction z, the two second elements 21B flank one of the pair of intermediate portions 326 in the second direction y. As viewed in the thickness direction z, one of the second elements 21B and the fourth element 21D are located on opposite sides of the other one of the pair of intermediate portions 326 in the second direction y.

As shown in FIG. 6, the third bond portions 322 are individually bonded to the first electrodes 212 of the two second elements 21B and the fourth element 21D. Each of the third bond portions 322 faces the first electrode 212 of one of the two second elements 21B and the fourth element 21D.

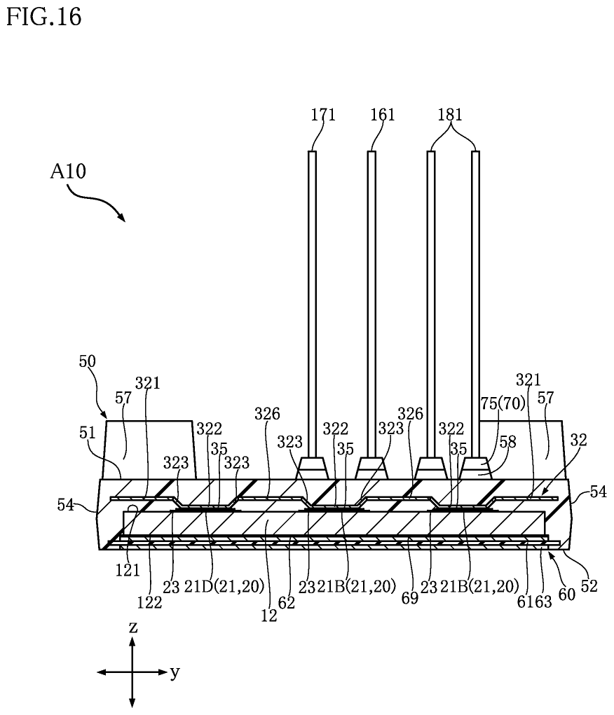

As shown in FIGS. 6 and 16, the third connecting portions 323 are connected to both sides in the second direction y of each third bond portion 322. Each of the third connecting portions 323 is connected to one of the main bodies 321 and intermediate portions 326. As viewed in the first direction x, each of the third connecting portions 323 is inclined to become farther away from the second obverse surface 122A of the second support layer 122 as proceeding from one of the third bond portions 322 toward one of the main bodies 321 and intermediate portions 326.

As shown in FIGS. 6 and 12, the pair of fourth bond portions 324 are bonded to the covered portion 15A of the second input terminal 15. The fourth bond portions 324 face the covered portion 15A.

As shown in FIGS. 6 and 12, the pair of fourth connecting portions 325 are connected to pair of main bodies 321 and the pair of fourth bond portions 324. As viewed in the second direction y, the fourth connecting portions 325 are inclined to become farther away from the first obverse surface 121A of the first support layer 121 as proceeding from the fourth bond portions 324 toward the main bodies 321.

As shown in FIGS. 6 and 15, the beam portions 327 are arranged side by side in the second direction y. As viewed in the thickness direction z, the beam portions 327 include portions individually overlapping with the first bond portions 312 of the first conductive member 31. The beam portion 327 located at the center in the second direction y is connected on its both sides in the second direction y to the intermediate portions 326. Each of the remaining two beam portions 327 is connected on its one side in the second direction y to one of the main bodies 321 and on its other side in the second direction y to one of the intermediate portions 326. As viewed in the first direction x, the beam portions 327 protrude toward the side which the first obverse surface 121A of the first support layer 121 faces in the thickness direction z.

As shown in FIG. 16, the semiconductor device A10 further includes a third conductive joining layer 35. The third conductive joining layer 35 is interposed between the first electrodes 212 of the two first elements 21A and the fourth element 21D, and the third bond portions 322. The third conductive joining layer 35 conductively bonds the first electrodes 212 of the two second elements 21B and the fourth element 21D to the third bond portions 322. The third conductive joining layer 35 may be solder, for example. Alternatively, the third conductive joining layer 35 may contain sintered metal particles.

As shown in FIG. 12, the semiconductor device A10 further includes a fourth conductive joining layer 36. The fourth conductive joining layer 36 is interposed between the covered portion 15A of the second input terminal 15 and the pair of fourth bond portions 324. The fourth conductive joining layer 36 conductively bonds the covered portion 15A and the fourth bond portions 324 to each other. The fourth conductive joining layer 36 may be solder, for example. Alternatively, the fourth conductive joining layer 36 may contain sintered metal particles.

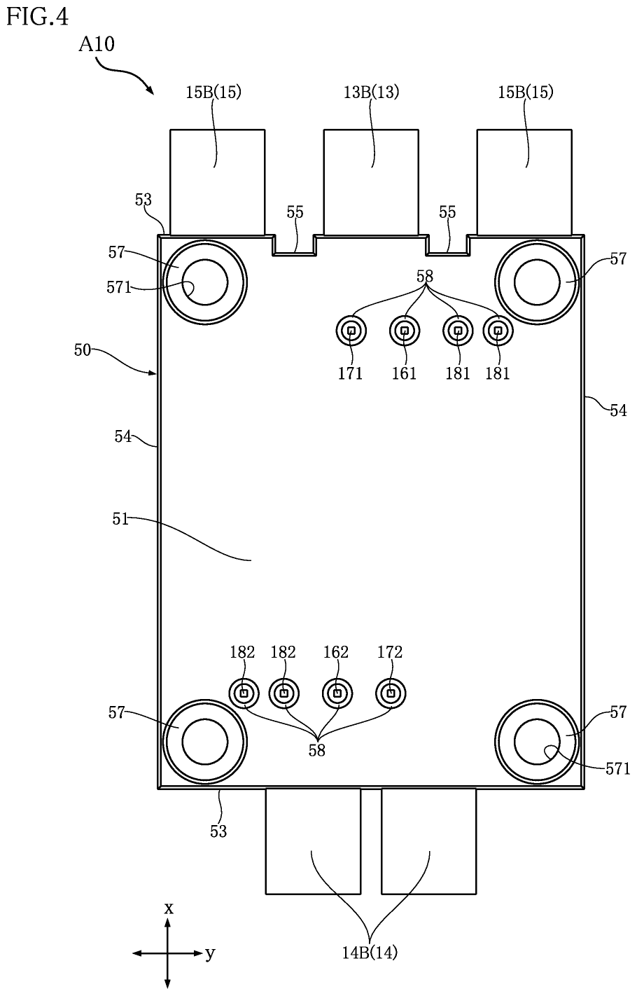

As shown in FIGS. 12, 13, 15 and 16, the sealing resin 50 covers the support layer 12, the semiconductor elements 21, the first conductive member 31 and the second conductive member 32. The sealing resin 50 further covers a part of each of the support member 11, the first input terminal 13, the output terminal 14 and the second input terminal 15. The sealing resin 50 has an electrically insulating property. The sealing resin 50 is made of a material containing black epoxy resin, for example. As shown in FIGS. 4 and 8 to 11, the sealing resin 50 has a top surface 51, a bottom surface 52, a pair of first side surfaces 53, a pair of second side surfaces 54, a pair of recesses 55, a pair of grooves 56, a plurality of first protrusions 57, and a plurality of second protrusions 58.

As shown in FIGS. 12 and 13, the top surface 51 faces the same side as the first obverse surface 121A of the first support layer 121 in the thickness direction z. As shown in FIGS. 12 and 13, the bottom surface 52 faces away from the top surface 51 in the thickness direction z. As shown in FIG. 9, the heat dissipation layer 113 of the support member 11 is exposed at the bottom surface 52.

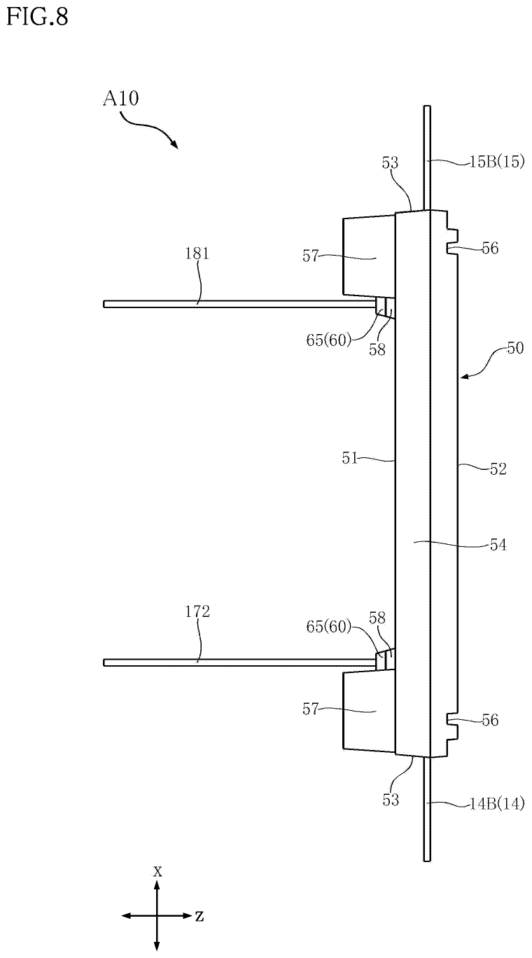

As shown in FIGS. 4 and 8, the pair of first side surfaces 53 are spaced apart from each other in the first direction x. The first side surfaces 53 face in the first direction x and extend in the second direction y. The first side surfaces 53 are connected to the top surface 51. As shown in FIG. 10, the exposed portion 13B of the first input terminal 13 and the exposed portion 15B of the second input terminal 15 are exposed at one of the first side surfaces 53. As shown in FIG. 11, the exposed portion 14B of the output terminal 14 is exposed at the other one of the first side surfaces 53.

As shown in FIGS. 4, 10 and 11, the pair of second side surfaces 54 are spaced apart from each other in the second direction y. The second side surfaces 54 face away from each other in the second direction y and extend in the first direction x. The second side surfaces 54 are connected to the top surface 51 and the bottom surface 52.

As shown in FIGS. 4, 9 and 10, the pair of recesses 55 are recessed in the first direction x from the first side surface 53 at which the exposed portion 13B of the first input terminal 13 and the exposed portion 15B of the second input terminal 15 are exposed. The recesses 55 extend from the top surface 51 to the bottom surface 52 in the thickness direction z. The recesses 55 flank the first input terminal 13 in the second direction y.

As shown in FIGS. 8, 9, 12 and 13, the pair of grooves 56 are recessed from the bottom surface 52 in the thickness direction z and extend in the second direction y. The opposite ends in the second direction y of each groove 56 are connected to the second side surfaces 54. The grooves 56 are spaced apart from each other in the first direction x. In the first direction x, the support layer 12 is located between the grooves 56.

As shown in FIGS. 8, 10 and 11, the first protrusions 57 protrude from the top surface 51 in the thickness direction z. As shown in FIG. 4, the first protrusions 57 are disposed at the four corners of the sealing resin 50 as viewed in the thickness direction z. Each of the first protrusions 57 has the outer shape of a truncated cone. As shown in FIGS. 4 and 12, each first protrusion 57 has a mounting hole 571 extending in the thickness direction z. The first protrusions 57 are used in mounting the semiconductor device A10 to a driver module. The driver module drives and controls the semiconductor device A10.

As shown in FIGS. 8, 10 and 11, the second protrusions 58 protrude from the top surface 51 in the thickness direction z. As shown in FIG. 4, the second protrusions 58 are individually disposed for the first gate terminal 161, the second gate terminal 162, the first detection terminal 171, the second detection terminal 172, the first diode terminals 181, and the second diode terminals 182. As shown in FIGS. 13 and 17, the second protrusions 58 individually cover the holders 64 of the control wirings 60. One end of each holder 64 is exposed from a second protrusion 58.

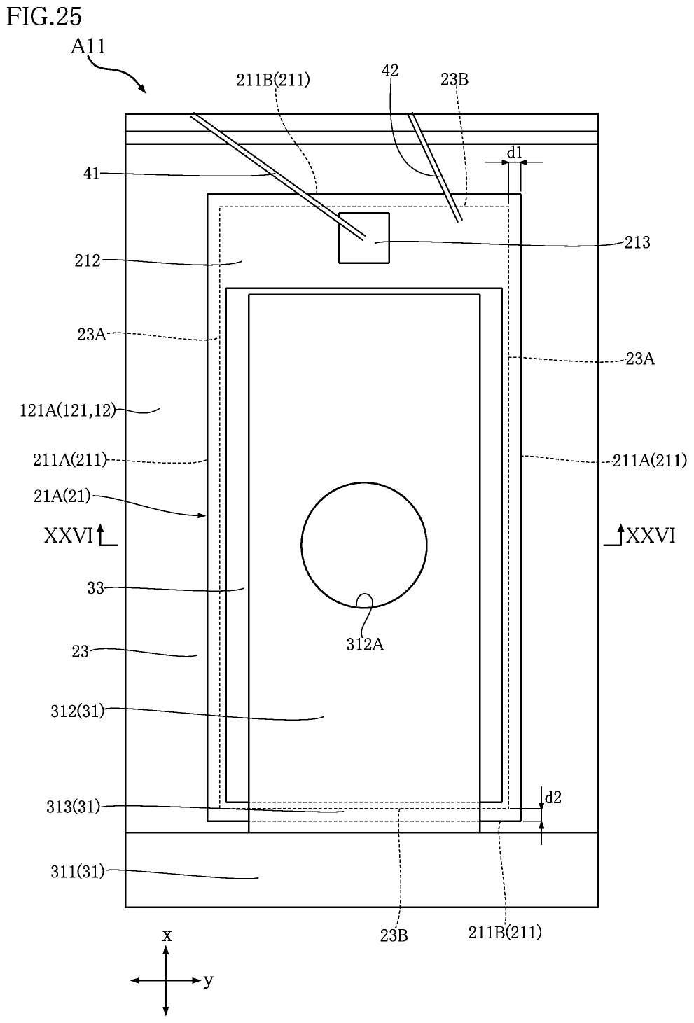

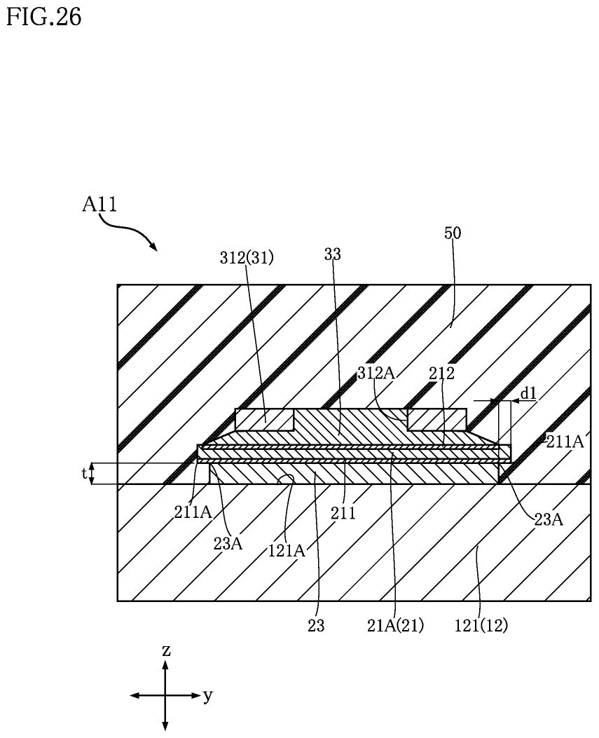

Next, a semiconductor device A11, which is a first variation of the semiconductor device A10, is described based on FIGS. 25 and 26. In FIG. 25, the sealing resin 50 is shown transparent for the convenience of understanding. FIG. 25 corresponds in position to FIG. 18.

As shown in FIGS. 25 and 26, in the semiconductor device A11, the relationship between the distance d1 and the thickness t of the joining layers 23 is −t≤d1<0. Also, the relationship between the distance d2 and the thickness t is −t≤d2<0. Therefore, as viewed in the thickness direction z, the periphery of the joining layers 23 including the second edge 23A and the fourth edge 23B overlaps with the element metal layer 211 of the semiconductor elements 21 and is surrounded by the periphery of the element metal layer 211 including the first edge 211A and the third edge 211B.

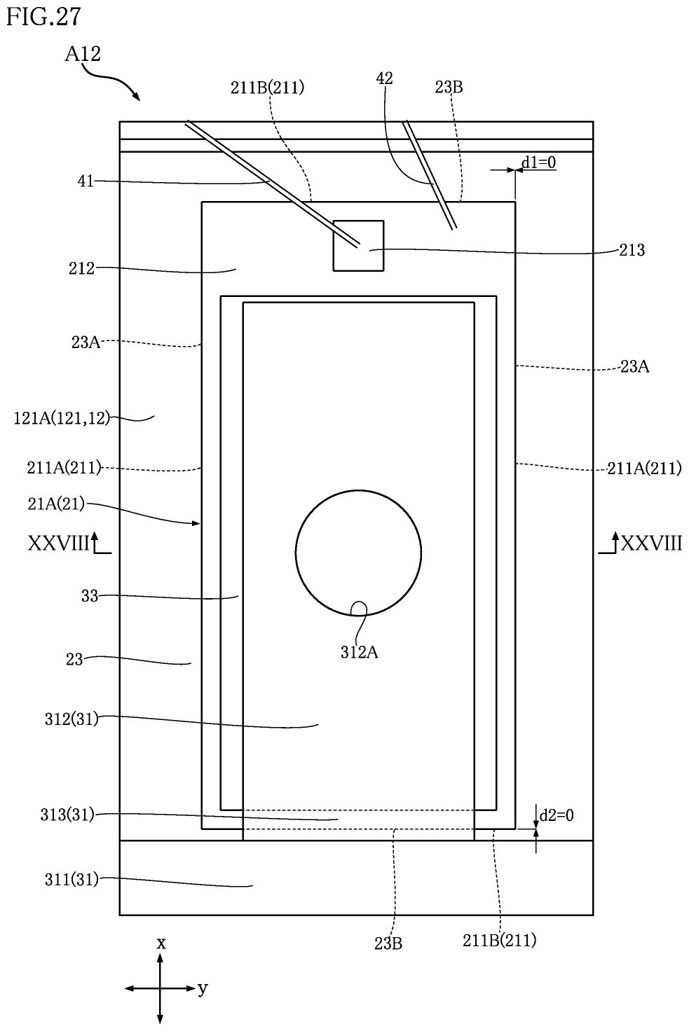

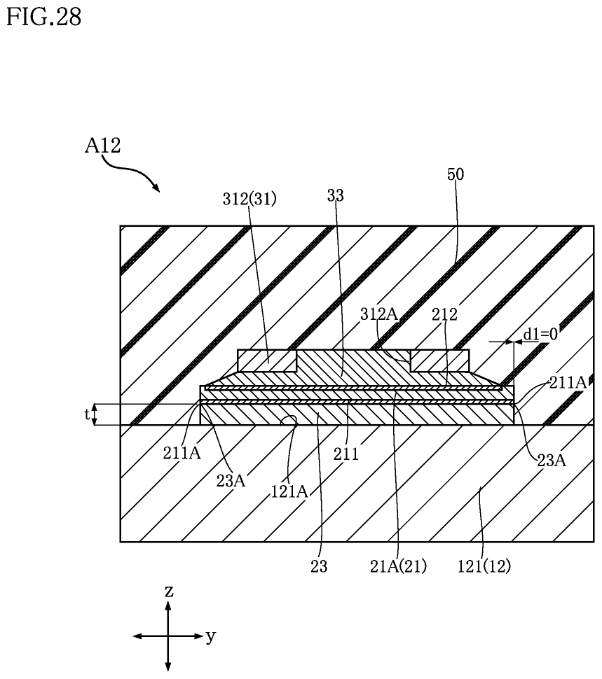

Next, a semiconductor device A12, which is a second variation of the semiconductor device A10, is described based on FIGS. 27 and 28. In FIG. 27, the sealing resin 50 is shown transparent for the convenience of understanding. FIG. 27 corresponds in position to FIG. 18.

As shown in FIGS. 27 and 28, in the semiconductor device A12, the distance d1 and the distance d2 are both 0. Thus, as viewed in the thickness direction z, the periphery of the joining layers 23 including the second edge 23A and the fourth edge 23B coincides with the periphery of the element metal layer 211 of the semiconductor elements 21 including the first edge 211A and the third edge 211B.

The advantages of the semiconductor device A10 are described below.

The semiconductor device A10 includes semiconductor elements 21 each having an element metal layer 211 facing the support layer 12 and joining layers 23 interposed between the support layer 12 and the element metal layers 211. Each element metal layer 211 has a first edge 211A. Each joining layer 23 has a second edge 23A. The relationship between the distance d (the distance d1) from the first edge 211A to the second edge 23A in the second direction y and the thickness t of the joining layers 23 is −t≤d≤2 t. With such a configuration, when the element metal layer 211 is bonded to the support layer 12 via the joining layer 23, the concentration of shear stress on the bonding interface between the support layer 12 and the element metal layer 211 is reduced. This strengthens the bonding state of the two material layers at the bonding interface. Thus, the semiconductor device A10 is capable of stabilizing the heat dissipation capability at the bonding interface between the support layer 12 and the semiconductor element 21 in the long term.

As viewed in the thickness direction z, the periphery of each joining layer 23 including the second edge 23A surrounds the periphery of the element metal layer 211 of a semiconductor element 21 including the first edge 211A. Such a configuration increases the area of the bonding interface between the support layer 12 and the element metal layer 211, thereby enhancing the bonding strength of the element metal layer 211 to the support layer 12. Also, the heat conduction efficiency of the joining layers 23 in a direction orthogonal to the thickness direction z is improved, which allows the heat generated from the semiconductor elements 21 to be conducted to the support layer 12 more quickly.

Additionally, when the support layer 12 contains a metal element and the composition of the joining layers 23 includes aluminum, a protrusion 232 that protrudes from the joining surface 231 in the thickness direction z forms on each joining layer 23. The protrusion 232 is located between the first edge 211A of the element metal layer 211 of the semiconductor element 21 and the second edge 23A of the joining layer 23 in the second direction y. The protrusion 232 forms as a result of bonding the element metal layer 211 to the support layer 12 via the joining layer 23 by solid-phase diffusion. The formation of the protrusion 232 on the joining layer 23 indicates that compressive stress was applied to the solid-phase diffusion bonding layer 24 interposed between the support layer 12 and the element metal layer 211 during solid-phase diffusion. Moreover, when the pitch p1 between the first edge 211A and the protrusion 232 in the second direction y is shorter than the pitch p2 between the protrusion 232 and the second edge 23A in the second direction y, it indicates that a large compressive stress was applied to the solid-phase diffusion bonding layer 24 during solid-phase diffusion. In this way, the bonding state of the solid-phase diffusion bonding layer 24 is further strengthened.

The element metal layer 211 of each semiconductor element 21 is electrically connected to a circuit provided in the semiconductor element 21. When the bonding of the two material layers at the bonding interface between the support layer 12 and the element metal layer 211 is strengthened, the long-term fluctuations of the current flowing through the bonding interface is suppressed during the use of the semiconductor device A10. Thus, the long-term stability can be achieved for the current flowing through the bonding interface between the support layer 12 and the semiconductor elements 21.

The semiconductor device A10 further includes a support member 11 located opposite to the semiconductor elements 21 with the support layer 12 interposed therebetween. The support layer 12 is bonded to the support member 11. The support member 11 includes the insulating layer 111, and the heat dissipation layer 113 located opposite to the support layer 12 with the insulating layer 111 interposed therebetween. With such a configuration, while using the support layer 12 as a conductive path in the semiconductor device A10, the heat conducted from the semiconductor elements 21 to the support layer 12 can be efficiently released to the outside of the semiconductor device A10. When the thickness of the heat dissipation layer 113 is larger than that of the insulating layer 111, the heat dissipation efficiency of the heat dissipation layer 113 in a direction orthogonal to the thickness direction z improves, which is desirable for the improvement of the heat dissipation of the semiconductor device A10.

The sealing resin 50 has the pair of recesses 55 that are recessed in the first direction x from one of the pair of the first side surfaces 53 at which the first input terminal 13 and the second input terminal 15 are exposed. The recesses 55 flank the first input terminal 13 in the second direction y. Such a configuration increases the distance along the surface, or creepage distance, of the sealing resin 50 between the first input terminal 13 and the second input terminal 15. Thus, the dielectric strength of the semiconductor device A10 can be improved.

The sealing resin 50 has the pair of grooves 56 recessed from the bottom surface 52 and spaced apart from each other in the first direction x. The grooves 56 extend in the second direction y. In the first direction x, the support layer 12 is located between the grooves 56. Such a configuration increases the distance along the surface, or creepage distance, of the sealing resin 50 between the first and the second input terminals 13 and 15 and the output terminal 14. Thus, the dielectric strength of the semiconductor device A10 can be further improved.

The composition of the first conductive member 31 and the second conductive member 32 includes copper. This reduces the electrical resistance of the first conductive member 31 and the second conductive member 32 as compared to the case in which the first conductive member 31 and the second conductive member 32 are wires containing aluminum in its composition. This is suitable for allowing a larger current to flow through the semiconductor elements 21.

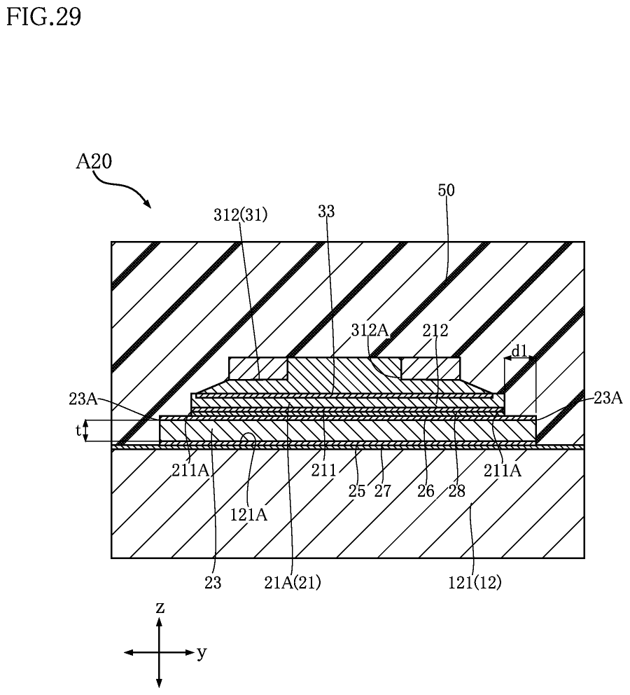

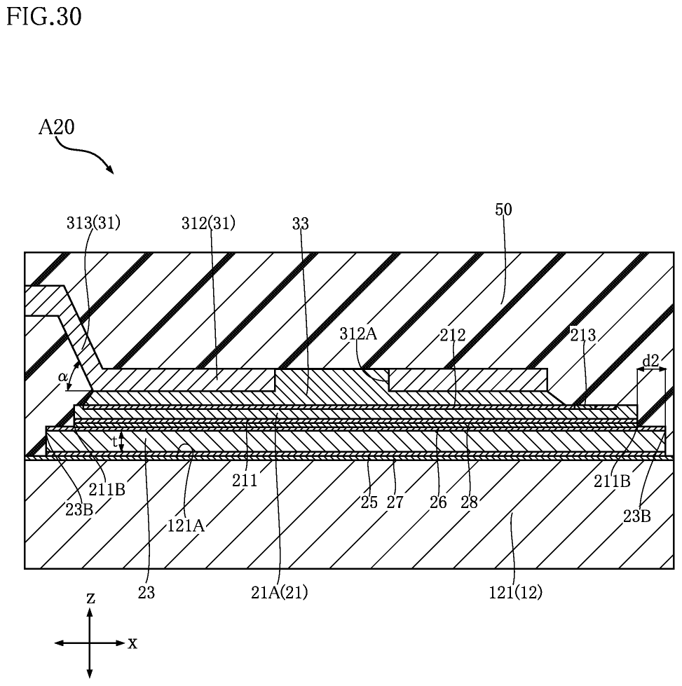

A semiconductor device A20 according to a second embodiment of the present disclosure is described below with reference to FIGS. 29 to 31. In the figures, the elements that are identical or similar to those of the foregoing semiconductor device A10 are denoted by the same reference signs as those used for the foregoing semiconductor device, and the description thereof is omitted. FIG. 29 corresponds in position to FIG. 19 of the semiconductor device A10. FIG. 30 corresponds in position to FIG. 22 of the semiconductor device A10.

The semiconductor device A20 differs from the semiconductor device A10 in that the semiconductor device A20 further includes a first metal layer 25, a second metal layer 26, a third metal layer 27, and a fourth metal layer 28. In the semiconductor device A20 again, the element metal layers 211 of the semiconductor elements 21 are bonded to the support layer 12 via the joining layers 23 by solid-phase diffusion. In the following description of the semiconductor device A20, of the plurality of semiconductor elements 21, the first element 21A is described as a representative.

As shown in FIGS. 29 to 31, the first metal layer 25 is interposed between the first support layer 121 (the support layer 12) and the joining layer 23. The first metal layer 25 is in contact with the joining layer 23. The composition of the first metal layer 25 includes silver. The second metal layer 26 is interposed between the joining layer 23 and the element metal layer 211 of the first element 21A. The second metal layer 26 is in contact with the joining layer 23. The composition of the second metal layer 26 includes silver.

As shown in FIGS. 29 to 31, the third metal layer 27 is interposed between the first support layer 121 and the first metal layer 25. The third metal layer 27 is in contact with the first obverse surface 121A of the first support layer 121. The composition of the third metal layer 27 includes silver. The fourth metal layer 28 is interposed between the second metal layer 26 and the element metal layer 211 of the first element 21A. The fourth metal layer 28 is in contact with the element metal layer 211. The composition of the fourth metal layer 28 includes silver.

The composition of the first metal layer 25, the second metal layer 26, the third metal layer 27 and the fourth metal layer 28 may include nickel (Ni) in addition to silver. In such a case, each of the first metal layer 25, the second metal layer 26, the third metal layer 27 and the fourth metal layer 28 includes a nickel layer, on which a silver layer is applied. The silver layer forming the first metal layer 25 and the silver layer forming the third metal layer 27 are located at the interface between the first metal layer 25 and the third metal layer 27. The silver layer forming the second metal layer 26 and the silver layer forming the fourth metal layer 28 are located at the interface between the second metal layer 26 and the fourth metal layer 28.

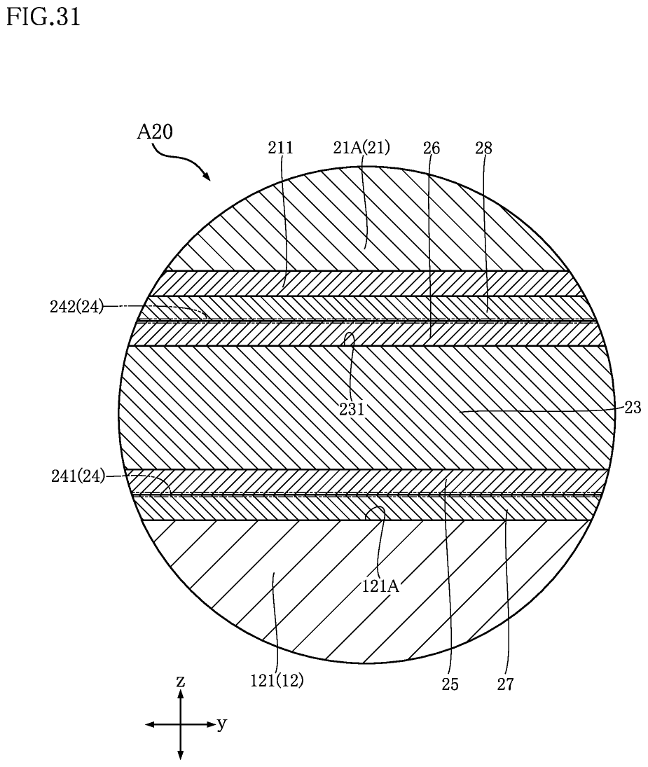

As shown in FIG. 31, the first bonding layer 241 of the solid-phase diffusion bonding layer 24 is located at the interface between the first metal layer 25 and the third metal layer 27. The second bonding layer 242 of the solid-phase diffusion bonding layer 24 is located at the interface between the second metal layer 26 and the fourth metal layer 28.

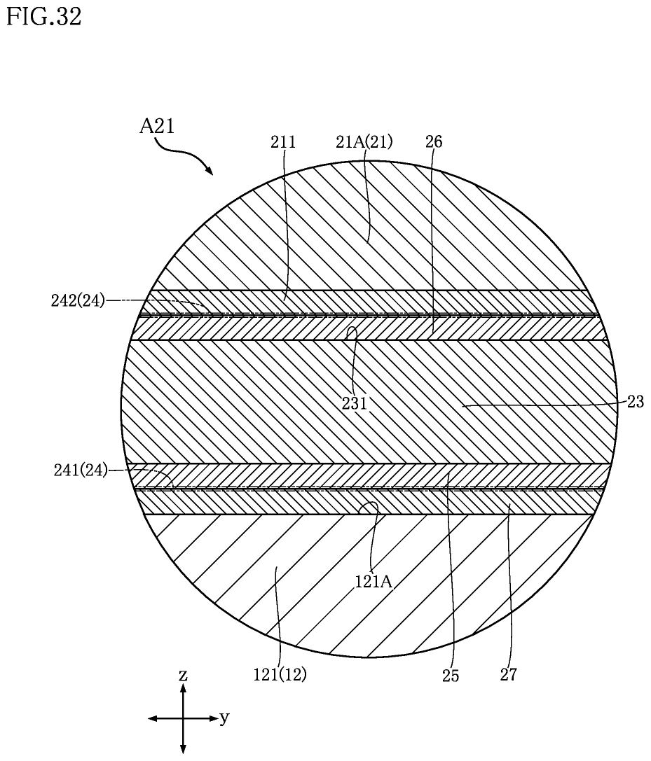

A semiconductor device A21 as a variation of the semiconductor device A20 is described below based on FIG. 32. FIG. 32 corresponds in position to FIG. 31.

As shown in FIG. 32, the semiconductor device A21 does not include the fourth metal layer 28. Thus, the second bonding layer 242 of the solid-phase diffusion bonding layer 24 is located at the interface between the second metal layer 26 and the element metal layer 211 of the first element 21A.

The advantages of the semiconductor device A20 are described below.

The semiconductor device A20 includes semiconductor elements 21 each having an element metal layer 211 facing the support layer 12 and joining layers 23 interposed between the support layer 12 and the element metal layers 211. Each element metal layer 211 has a first edge 211A. Each joining layer 23 has a second edge 23A. The relationship between the distance d (the distance d1) from the first edge 211A to the second edge 23A in the second direction y and the thickness t of the joining layers 23 is −t≤d≤2 t. Therefore, the semiconductor device A20 is also capable of stabilizing the heat dissipation capability at the bonding interface between the support layer 12 and the semiconductor element 21 in the long term. The semiconductor device A20 has a configuration similar to that of the semiconductor device A10, thereby achieving the same advantages as the semiconductor device A10.

The semiconductor device A20 further includes the first metal layer 25, the second metal layer 26, and the third metal layer 27. The first metal layer 25 and the second metal layer 26 are in contact with the joining layer 23. The third metal layer 27 is in contact with the support layer 12. The composition of the first metal layer 25, the second metal layer 26 and the third metal layer 27 includes silver. In this case, the first bonding layer 241 of the solid-phase diffusion bonding layer 24 is located at the interface between the first metal layer 25 and the third metal layer 27. When metal layers each including silver in its composition are bonded together by solid-phase diffusion, the strength of the metallic bond is relatively high. Thus, the bonding state in the solid-phase diffusion bonding layer 24 can be further strengthened.

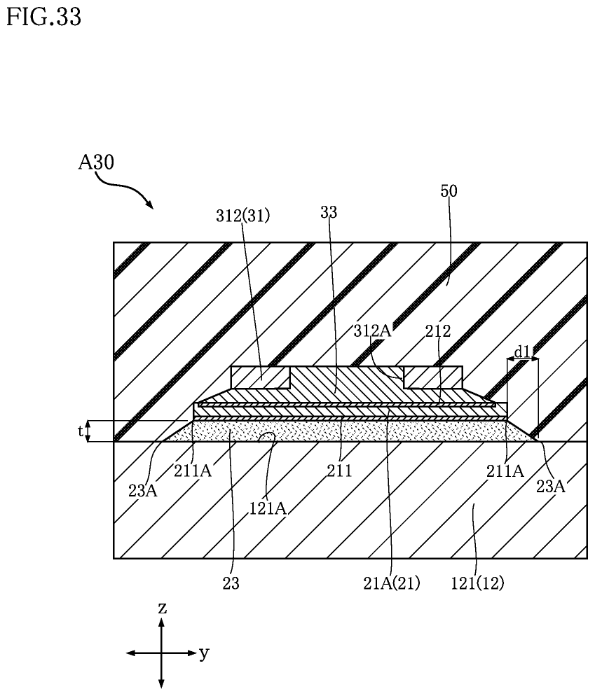

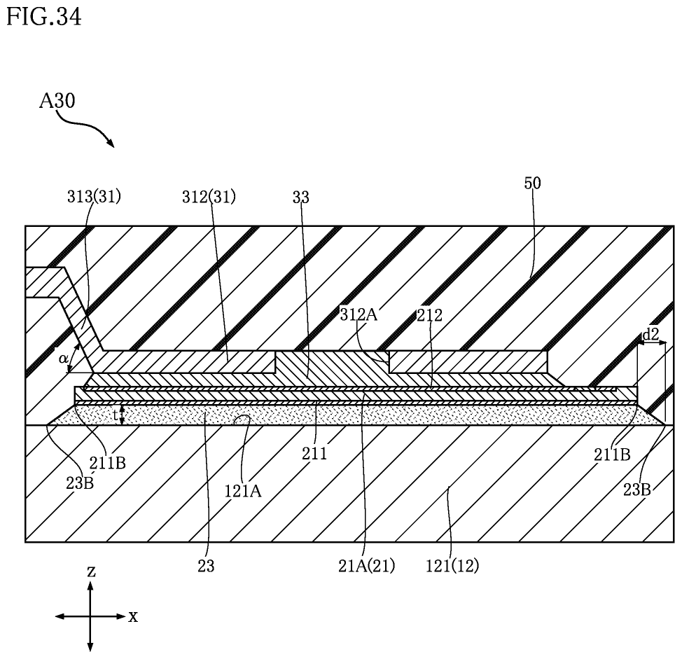

A semiconductor device A30 according to a third embodiment of the present disclosure is described below with reference to FIGS. 33 to 34. In the figures, the elements that are identical or similar to those of the foregoing semiconductor device A10 are denoted by the same reference signs as those used for the foregoing semiconductor device, and the description thereof is omitted. FIG. 33 corresponds in position to FIG. 19 of the semiconductor device A10. FIG. 34 corresponds in position to FIG. 22 of the semiconductor device A10.

The semiconductor device A30 differs from the semiconductor device A10 in configuration of the joining layer 23. In the semiconductor device A30, the element metal layers 211 of the semiconductor elements 21 are bonded to the support layer 12 via the joining layers 23 by sintering.

The joining layer 23 contains sintered metal particles. The composition of the sintered particles includes silver or copper.

In the semiconductor device A30 again, −t≤d1≤2 t holds for the distance d1 and the thickness t of the joining layer 23 shown in FIG. 33. Also, −t≤d2≤2 t holds for the distance d2 and the thickness t shown in FIG. 34.

The advantages of the semiconductor device A30 are described below.

The semiconductor device A30 includes semiconductor elements 21 each having an element metal layer 211 facing the support layer 12 and joining layers 23 interposed between the support layer 12 and the element metal layers 211. Each element metal layer 211 has a first edge 211A. Each joining layer 23 has a second edge 23A. The relationship between the distance d (the distance d1) from the first edge 211A to the second edge 23A in the second direction y and the thickness t of the joining layers 23 is −t≤d≤2 t. Therefore, the semiconductor device A30 is also capable of stabilizing the heat dissipation capability at the bonding interface between the support layer 12 and the semiconductor element 21 in the long term. The semiconductor device A30 has a configuration similar to that of the semiconductor device A10, thereby achieving the same advantages as the semiconductor device A10.

The present disclosure is not limited to the foregoing embodiments. The specific configuration of each part of the present disclosure can be varied in design in many ways.

The present disclosure includes the embodiments described in the following clauses.

Clause 1.

A semiconductor device comprising:
a support layer;
a semiconductor element including an element metal layer facing the support layer; and
a joining layer interposed between the support layer and the element metal layer, wherein
the element metal layer includes a first edge extending in a first direction orthogonal to a thickness direction of the semiconductor element,
the joining layer includes a second edge located closest to the first edge and extending in the first direction, and
when the second edge is spaced apart from the element metal layer as viewed in the thickness direction, a distance from the first edge to the second edge in a second direction orthogonal to the thickness direction and the first direction is equal to or less than twice a thickness of the joining layer.

Clause 2.

The semiconductor device according to clause 1, wherein, when the second edge overlaps with the element metal layer as viewed in the thickness direction, the distance from the first edge to the second edge in the second direction is equal to or less than the thickness of the joining layer.

Clause 3.

The semiconductor device according to clause 1, wherein, as viewed in the thickness direction, a periphery of the joining layer that includes the second edge surrounds a periphery of the element metal layer that includes the first edge.

Clause 4.

The semiconductor device according to clause 3, wherein the support layer contains a metal element.

Clause 5.

The semiconductor device according to clause 4, wherein the metal element is copper.

Clause 6.

The semiconductor device according to clause 4 or 5, further comprising a solid-phase diffusion bonding layer interposed between the support layer and the element metal layer, wherein
the joining layer contains aluminum,
the solid-phase diffusion bonding layer is interposed between the support layer and the element metal layer, and
the solid-phase diffusion bonding layer includes a first bonding layer located between the support layer and the joining layer and a second bonding layer located between the joining layer and the element metal layer.

Clause 7.

The semiconductor device according to clause 6, further comprising:
a first metal layer interposed between the support layer and the joining layer;
a second metal layer interposed between the joining layer and the element metal layer; and
a third metal layer interposed between the support layer and the first metal layer, wherein the first metal layer and the second metal layer are in contact with the joining layer, the third metal layer is in contact with the support layer,
the first bonding layer is located at an interface between the first metal layer and the third metal layer, and
the second bonding layer is located between the second metal layer and the element metal layer.

Clause 8.

The semiconductor device according to clause 7, wherein each of the first metal layer, the second metal layer and the third metal layer contains silver.

Clause 9.

The semiconductor device according to clause 7 or 8, further comprising a fourth metal layer interposed between the second metal layer and the element metal layer, wherein
the fourth metal layer is in contact with the element metal layer, and
the second bonding layer is located at an interface between the second metal layer and the fourth metal layer.

Clause 10.

The semiconductor device according to clause 9, wherein the fourth metal layer contains silver.

Clause 11.

The semiconductor device according to any one of clauses 6 to 10, wherein the joining layer includes a joining surface facing the element metal layer,
the joining layer is formed with a protrusion that protrudes from the joining surface in the thickness direction, and
the protrusion is located between the first edge and the second edge in the second direction.

Clause 12.

The semiconductor device according to clause 11, wherein a pitch between the first edge and the protrusion in the second direction is shorter than a pitch between the protrusion and the second edge in the second direction.

Clause 13.

The semiconductor device according to clause 4 or 5, wherein the joining layer contains sintered metal particles.

Clause 14.

The semiconductor device according to clause 13, wherein the sintered metal particles contain silver or copper.

Clause 15.

The semiconductor device according to any one of clauses 4 to 14, further comprising a support member located opposite to the semiconductor element with the support layer interposed therebetween, wherein
the support member includes an insulating layer, and
the support layer is bonded to the support member.

Clause 16.

The semiconductor device according to clause 15, wherein a thickness of the insulating layer is smaller than a thickness of the support layer.

Clause 17.

The semiconductor device according to clause 16, wherein the support member includes a heat dissipation layer located opposite to the support layer with the insulating layer interposed therebetween, and
a thickness of the heat dissipation layer is larger than a thickness of the insulating layer.

Clause 18.

The semiconductor device according to any one of clauses 15 to 17, wherein the element metal layer is electrically connected to the support layer and a circuit provided in the semiconductor element.

### REFERENCE NUMERALS

A10, A20, A30: Semiconductor device 11: Support member
111: Insulating layer 112: Intermediate layer
113: Heat dissipation layer
12: Support layer 121: First support layer
121A: First obverse surface
121B: First reverse surface 122: Second support layer
122A: Second obverse surface
122B: Second support layer 13: First input terminal
13A: Covered portion
13B: Exposed portion 14: Output terminal
14A: Covered portion
14B: Exposed portion 15: Second input terminal
15A: Covered portion
15B: Exposed portion 161: First gate terminal
162: Second gate terminal 171: First detection terminal
172: Second detection terminal 181: First diode terminal
182: Second diode terminal 19: First adhesive layer
21: Semiconductor element 21A: First element
21B: Second element 21C: Third element
21D: Fourth element
211: Element metal layer 211A: First edge
211B: Third edge
212: First electrode 213: Second electrode
214: Third electrode
215: Fourth electrode 23: Joining layer 23A: Second edge
23B: Fourth edge 231: Joining surface 232: Protrusion
24: Solid-phase diffusion bonding layer
241: First bonding layer 242: Second bonding layer
25: First metal layer 26: Second metal layer
27: Third metal layer
28: Fourth metal layer 31: First conductive member
311: Main body
312: First bond portion 312A: Opening
313: First connecting portion
314: Second bond portion 315: Second connecting portion
32: Second conductive member
321: Main body 322: Third bond portion 322A: Opening
323: Third connecting portion 324: Fourth bond portion
325: Fourth connecting portion
326: Intermediate portion 327: Beam portion
33: First conductive joining layer
34: Second conductive joining layer
35: Third conductive joining layer
36: Fourth conductive joining layer 41: Gate wire
42: Detection wire 43: Diode wire
50: Sealing resin 51: Top surface 52: Bottom surface
53: First side surface 54: Second side surface
55: Recess
56: Groove 57: First protrusion 571: Mounting hole
58: Second protrusion 60: Control wiring
601: First wiring
602: Second wiring 61: Insulating layer 62: Wiring layer
621: First wiring layer 622: Second wiring layer
623: Third wiring layer
63: Metal layer 64: Holder 65: Covering layer
68: Second adhesive layer 69: Third adhesive layer
t: Thickness
d1, d2: Distance p1, p2, p3, p4: Pitch
z: Thickness direction x: First direction
y: Second direction

1. A semiconductor device comprising:
a support layer;
a semiconductor element including an element metal layer facing the support layer; and
a joining layer interposed between the support layer and the element metal layer, wherein
the element metal layer includes a first edge extending in a first direction orthogonal to a thickness direction of the semiconductor element,
the joining layer includes a second edge located closest to the first edge and extending in the first direction, and
when the second edge is spaced apart from the element metal layer as viewed in the thickness direction, a distance from the first edge to the second edge in a second direction orthogonal to the thickness direction and the first direction is equal to or less than twice a thickness of the joining layer.

2. The semiconductor device according to claim 1, wherein, when the second edge overlaps with the element metal layer as viewed in the thickness direction, the distance from the first edge to the second edge in the second direction is equal to or less than the thickness of the joining layer.

3. The semiconductor device according to claim 1, wherein, as viewed in the thickness direction, a periphery of the joining layer that includes the second edge surrounds a periphery of the element metal layer that includes the first edge.

4. The semiconductor device according to claim 3, wherein the support layer contains a metal element.

5. The semiconductor device according to claim 4, wherein the metal element is copper.

6. The semiconductor device according to claim 4, further comprising a solid-phase diffusion bonding layer interposed between the support layer and the element metal layer, wherein
the joining layer contains aluminum, and
the solid-phase diffusion bonding layer includes a first bonding layer located between the support layer and the joining layer and a second bonding layer located between the joining layer and the element metal layer.

7. The semiconductor device according to claim 6, further comprising:
a first metal layer interposed between the support layer and the joining layer;
a second metal layer interposed between the joining layer and the element metal layer; and
a third metal layer interposed between the support layer and the first metal layer, wherein
the first metal layer and the second metal layer are in contact with the joining layer,
the third metal layer is in contact with the support layer,
the first bonding layer is located at an interface between the first metal layer and the third metal layer, and
the second bonding layer is located between the second metal layer and the element metal layer.

8. The semiconductor device according to claim 7, wherein each of the first metal layer, the second metal layer and the third metal layer contains silver.

9. The semiconductor device according to claim 7, further comprising a fourth metal layer interposed between the second metal layer and the element metal layer, wherein
the fourth metal layer is in contact with the element metal layer, and
the second bonding layer is located at an interface between the second metal layer and the fourth metal layer.

10. The semiconductor device according to claim 9, wherein the fourth metal layer contains silver.

11. The semiconductor device according to claim 6, wherein the joining layer includes a joining surface facing the element metal layer,
the joining layer is formed with a protrusion that protrudes from the joining surface in the thickness direction, and
the protrusion is located between the first edge and the second edge in the second direction.

12. The semiconductor device according to claim 11, wherein a pitch between the first edge and the protrusion in the second direction is shorter than a pitch between the protrusion and the second edge in the second direction.

13. The semiconductor device according to claim 4, wherein the joining layer contains sintered metal particles.

14. The semiconductor device according to claim 13, wherein the sintered metal particles contain silver or copper.

15. The semiconductor device according to claim 4, further comprising a support member located opposite to the semiconductor element with the support layer interposed therebetween, wherein
the support member includes an insulating layer, and
the support layer is bonded to the support member.

16. The semiconductor device according to claim 15, wherein a thickness of the insulating layer is smaller than a thickness of the support layer.

17. The semiconductor device according to claim 16, wherein the support member includes a heat dissipation layer located opposite to the support layer with the insulating layer interposed therebetween, and
a thickness of the heat dissipation layer is larger than a thickness of the insulating layer.

18. The semiconductor device according to claim 15, wherein the element metal layer is electrically connected to the support layer and a circuit provided in the semiconductor element.
